(19) United States
(12) Patent Application Publication
(10) Pub. No.: US 2025/0169336 A1
(43) Pub. Date: May 22, 2025

(54) DISPLAY DEVICE AND METHOD FOR MANUFACTURING THE SAME

(71) Applicant: Samsung Display Co., Ltd., Yongin-si (KR)

(72) Inventors: HEEYEON PARK, Yongin-si (KR); YEONGUK KIM, Yongin-si (KR); CHANGYEONG SONG, Yongin-si (KR); Hyein JUNG, Yongin-si (KR); YONGCHAN JU, Yongin-si (KR); JAEHEUNG HA, Yongin-si (KR)

(21) Appl. No.: 18/926,737

(22) Filed: Oct. 25, 2024

(30) Foreign Application Priority Data
Nov. 20, 2023 (KR) 10-2023-0160556

(51) Int. Cl. H10K 59/80; C09D 1/00; C09D 183/16; H10K 59/12; H10K 59/124

(52) U.S. Cl. CPC H10K 59/873; C09D 1/00; C09D 183/16; H10K 59/1201; H10K 59/124

(57) ABSTRACT

A display device includes: a circuit layer including a transistor and a plurality of insulating layers, a display element layer disposed on the circuit layer and including a light emitting element electrically connected to the transistor, an inorganic encapsulation film disposed on the display element layer, and a barrier layer directly disposed on the inorganic encapsulation film and containing an inorganic polysilazane compound.

This application claims priority to Korean Patent Application No. 10-2023-0160556, filed on Nov. 20, 2023, and all the benefits accruing therefrom under 35 U.S.C. § 119, the content of which in its entirety is herein incorporated by reference.

### BACKGROUND

The present disclosure herein relates to a display device and a method for manufacturing the same, and more particularly, to a display device including a barrier layer and a method for manufacturing the same.

Display devices for providing users with images, such as televisions, mobile phones, tablets, computers, navigation systems, and game consoles, may be provided with display panels for generating and displaying images. The display devices may be devices provided with multiple electronic components such as input sensors for sensing external inputs and electronic modules, in addition to the display panels. The electronic modules may include cameras, infrared sensors, or proximity sensors.

In a recent effort to provide users with a greater area of a display region, the electronic modules of the display devices are placed below the display panels, and the display panels may be provided with holes for exposing the electronic modules. In addition, there is a desire for technologies designed to protect some layers of the display panels exposed around the holes for the reliability of such display devices.

### SUMMARY

The present disclosure provides a display device prepared through simplified manufacturing processes and having improved product reliability.

The present disclosure also provides a method for manufacturing a display device, where the method provides a barrier layer having a sufficient thickness through a printing method to replace the composition of an organic encapsulation film and an upper inorganic encapsulation film, and may thus simplify processes and improve the reliability of the display device.

An embodiment of the invention provides a display device including: a circuit layer including a transistor and a plurality of insulating layers, a display element layer disposed on the circuit layer and including a light emitting element electrically connected to the transistor, an inorganic encapsulation film disposed on the display element layer, and a barrier layer directly disposed on the inorganic encapsulation film and containing an inorganic polysilazane compound.

In an embodiment, the barrier layer may include an inorganic polymer layer containing silicon (Si) and nitrogen (N), or an inorganic polymer layer containing Si, N, and oxygen (O).

In an embodiment, the barrier layer may have a refractive index of about 1.59 to about 1.90.

In an embodiment, the barrier layer may have a refractive index at a first portion adjacent to the inorganic encapsulation film, which is smaller than a refractive index at a second portion spaced apart from the inorganic encapsulation film.

In an embodiment, the barrier layer may have a refractive index increasing in a direction away from the inorganic encapsulation film.

In an embodiment, a first portion of the barrier layer, which is adjacent to the inorganic encapsulation film, may include a silazane-based compound having a repeating unit of Formula 1 below, and a second portion of the barrier layer, which is positioned on the first portion, may include silicon nitride or silicon oxynitride. In Formula 1 below, R₁ and R₂ are each independently a hydrogen atom, an alkyl group having 1 to 10 carbon atoms, or an aryl group having 6 to 30 ring-forming carbon atoms, and n is an integer of 2 or greater:

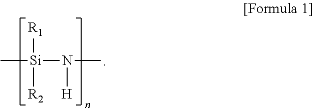

In an embodiment, the barrier layer may have a thickness of about 1,000 Å to about 100,000 Å.

In an embodiment, when the thickness of the barrier layer is about 3,000 angstroms (Å) or less, the barrier layer may be a silicon nitride layer or a silicon oxynitride layer.

In an embodiment of the invention, a display device includes: an electronic module, and a display module including a hole region including a hole defined to overlap the electronic module, and a display region spaced apart from the hole in a plan view, and the display module includes a base layer, a circuit layer disposed on the base layer and including a plurality of insulating layers, a display element layer disposed on the circuit layer and including a light emitting element and a pixel defining film, a plurality of dam portions disposed on the base layer in the hole region, an inorganic encapsulation film covering the display element layer and the dam portions, and a barrier layer directly disposed on the inorganic encapsulation film and containing an inorganic polysilazane compound.

In an embodiment, the dam portions may include a first dam portion surrounding the hole, and a second dam portion surrounding the first dam portion in the plan view, and a groove may be defined between the first dam portion and the second dam portion.

In an embodiment, the groove may be filled with the barrier layer.

In an embodiment, the first dam portion and the second dam portion may each include: a first dam layer disposed in the same layer as one of the plurality of insulating layers, a second dam layer disposed in the first dam layer, and a conductive pattern including a tip portion protruding in a direction toward the inside of the groove and a direction away from the groove, and disposed between the first dam layer and the second dam layer.

In an embodiment, the plurality of insulating layers may include a lower insulating layer including a plurality of inorganic films sequentially disposed on the base layer, a first organic film disposed on the lower insulating layer, and a second organic film disposed on the first organic film, and the first dam layer may be disposed in the same layer as the first organic film, and the second dam layer may be disposed in the same layer as the second organic film.

In an embodiment, the groove may include a first concave portion defined by the first dam layer, and a second concave portion defined by the second dam layer on the first concave portion, and the barrier layer may cover a lower surface of the tip portion and fill the first concave portion.

In an embodiment, the barrier layer may include an inorganic polymer layer containing Si and N, or an inorganic polymer layer containing Si, N, and O, and the barrier layer may have a refractive index of about 1.59 to about 1.90.

In an embodiment, the barrier layer may have a refractive index at a first portion adjacent to the inorganic encapsulation film, which is smaller than a refractive index at a second portion spaced apart from the inorganic encapsulation film.

In an embodiment of the invention, a method for manufacturing a display device includes: providing a base layer including a hole region in which a through-hole is defined, and a display region adjacent to the hole region; forming a circuit layer including a conductive pattern and a plurality of insulating layers on the base layer; forming a plurality of dam portions including a dam layer disposed in the same layer as some of the insulating layers, where the dam portions define a groove in the hole region; forming a display element layer including a light emitting element on the circuit layer; forming an inorganic encapsulation film covering the light emitting element and the dam portions; and forming a barrier layer directly disposed on the inorganic encapsulation film and containing an inorganic polysilazane compound.

In an embodiment, the forming of the barrier layer may include providing a silazane resin composition through a method of inkjet printing to form a preliminary barrier layer, and irradiating the preliminary barrier layer with laser light to form the barrier layer.

In an embodiment, the silazane resin composition may include a silazane compound containing a unit represented by Formula 1 below and an organic solvent. In Formula 1 below, R₁ and R₂ are each independently a hydrogen atom, an alkyl group having 1 to 10 carbon atoms, or an aryl group having 6 to 30 ring-forming carbon atoms, and n is an integer of 2 or greater:

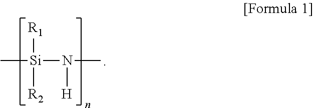

In an embodiment, the laser light may be a laser having a wavelength of about 172 nanometers (nm), and the forming of the barrier layer may be performed in an N₂ atmosphere or an O₂ atmosphere.

### BRIEF DESCRIPTION OF THE FIGURES

The accompanying drawings are included to provide a further understanding of the invention, and are incorporated in and constitute a part of this specification. The drawings illustrate embodiments of the invention and, together with the description, serve to explain principles of the invention. In the drawings:

FIG. 1 is a perspective view showing a display device of an embodiment;

FIG. 2 is an exploded perspective view showing a display device of an embodiment;

FIG. 3 is a cross-sectional view of a display module according to an embodiment;

FIG. 4 is a plan view showing a portion of a display module according to an embodiment;

FIG. 5 is a cross-sectional view showing a portion of a display module according to an embodiment;

FIG. 6 is a cross-sectional view showing a portion of a display module according to an embodiment;

FIG. 7 is a cross-sectional view showing region AA′ of FIG. 6;

FIG. 8A is a cross-sectional view schematically showing enlarged region BB′ of FIG. 7;

FIG. 8B is a cross-sectional view schematically showing enlarged region BB′ of FIG. 7;

FIG. 9 is a cross-sectional view showing a portion of a display module according to another embodiment;

FIG. 10 is a cross-sectional view showing region CC′ of FIG. 9;

FIGS. 11A to 11C are each a view schematically showing a step in a method for manufacturing a display device according to an embodiment;

FIG. 12 is a block diagram briefly showing a step of forming a barrier layer according to an embodiment; and

FIG. 13 is a graph showing the results of evaluating light transmittance of a barrier layer.

### DETAILED DESCRIPTION

The present disclosure may be modified in many alternate forms, and thus specific embodiments will be exemplified in the drawings and described in detail. It should be understood, however, that it is not intended to limit the present disclosure to the particular forms disclosed, but rather, is intended to cover all modifications, equivalents, and alternatives falling within the spirit and scope of the present disclosure.

It will be understood that when an element (or a region, a layer, a portion, or the like) is referred to as “being on”, “connected to” or “coupled to” another element, it may be directly disposed on, connected or coupled to the other element, or intervening elements may be disposed therebetween.

Like reference numerals refer to like elements. In addition, in the drawings, the thickness, the ratio, and the dimensions of elements are exaggerated for an effective description of technical contents. The term “and/or,” includes all combinations of one or more of which associated configurations may define. Throughout the disclosure, the expression “at least one of a, b or c” indicates only a, only b, only c, both a and b, both a and c, both b and c, all of a, b, and c, or variations thereof.

It will be understood that, although the terms “first”, “second”, etc. may be used herein to describe various elements, these elements should not be limited by these terms. These terms are only used to distinguish one element from another element. For example, a first element may be referred to as a second element, and similarly, a second element may be referred to as a first element without departing from the teachings of the present disclosure. The singular forms are intended to include the plural forms as well, unless the context clearly indicates otherwise.

Also, terms of “below”, “on lower side”, “above”, “on upper side”, or the like may be used to describe the relationships of the components shown in the drawings. The terms are used as a relative concept and are described with reference to the direction indicated in the drawings.

It should be understood that the terms “comprise”, or “have” are intended to specify the presence of stated features, integers, steps, operations, elements, components, or combinations thereof in the disclosure, but do not preclude the presence or addition of one or more other features, integers, steps, operations, elements, components, or combinations thereof.

As used herein, being “disposed directly on” may mean that there is no additional layer, film, region, plate, or the like between a part and another part such as a layer, a film, a region, a plate, or the like. For example, being “disposed directly on” may mean that two layers or two members are disposed without using an additional member such as an adhesive member, therebetween.

Unless otherwise defined, all terms (including technical and scientific terms) used herein have the same meaning as commonly understood by one of ordinary skill in the art to which the present disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

Hereinafter, a display device according to an embodiment and a method for manufacturing the same will be described with reference to the accompanying drawings.

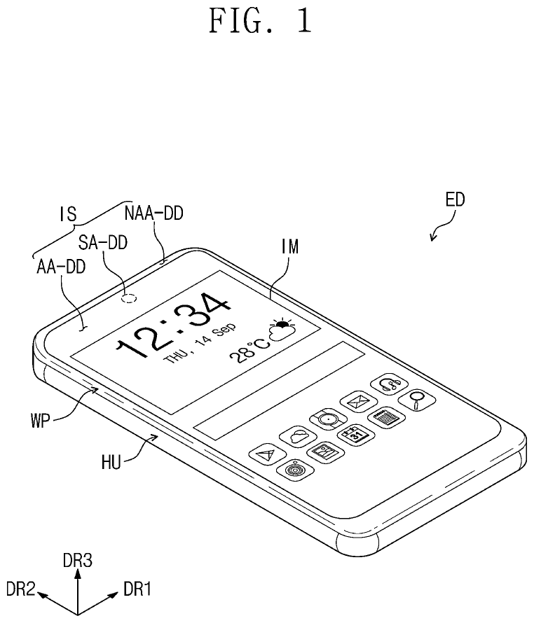

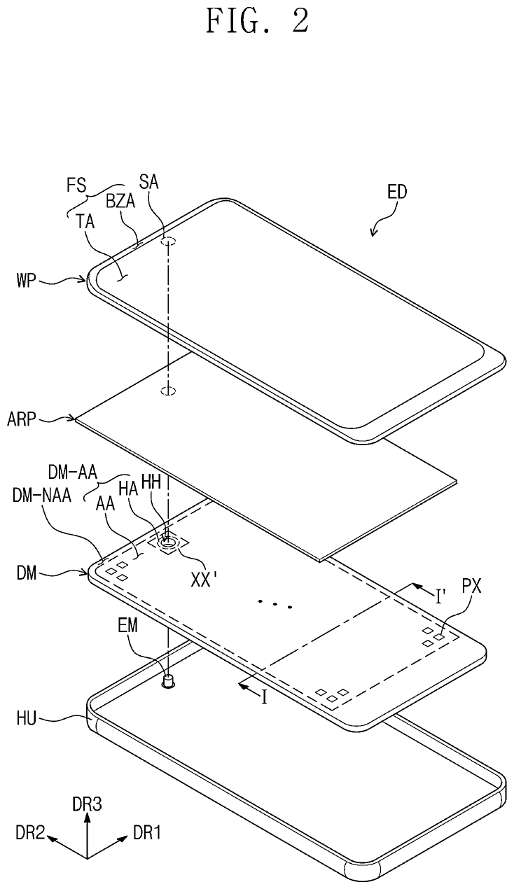

FIG. 1 is a perspective view of a display device according to an embodiment. FIG. 2 is an exploded perspective view of a display device according to an embodiment.

A display device ED may be a device activated according to electrical signals and display images. The display device ED may include various embodiments that provide users with images, and for example, the display device ED may not only include large-sized devices such as television sets and outdoor billboards, but also include small- and medium-sized devices such as monitors, mobile phones, computers, tablets, navigation systems, and game consoles. Meanwhile, embodiments of the display device ED are presented as examples and thus are not limited to any one without departing from the invention. Herein, a mobile phone is shown as an example of the display device ED in FIG. 1 and the like.

Referring to FIG. 1, the display device ED may have a rectangular shape having short sides extending in a first direction DR1 and long sides extending in a second direction DR2 when viewed on a plane (i.e., in a plan view). However, the embodiment of the invention is not limited thereto, and the display device ED may have various shapes such as a circular shape and a polygonal shape.

The display device ED may display an image IM in a third direction DR3 through a display surface IS parallel to a plane defined by the first direction DR1 and the second direction DR2. The third direction DR3 may be substantially parallel to a normal direction of the display surface IS. The display surface IS of the display device ED may correspond to a front surface of the display device ED.

The image IM displayed in the display device ED may include still images as well as dynamic images. In FIG. 1, a watch window and a plurality of icons are shown as an example of the image IM.

In an embodiment, a front surface (or an upper surface) and a rear surface (or a lower surface) of respective members or units may be defined with respect to the direction in which the image IM is displayed. The front and rear surfaces may oppose each other in the third direction DR3 and the normal direction of each of the front and rear surfaces may be substantially parallel to the third direction DR3. The distance between the front surface and the rear surface defined along the third direction DR3 may correspond to a thickness of a member (or a unit).

In addition, herein, “when viewed on a plane” (i.e., in a plan view) may be defined as a state viewed in a thickness direction (i.e., the third direction DR3) of the base layer BS. In addition, herein, “when viewed on a cross-section” may be defined as a state viewed in the first direction DR1 or the second direction DR2. Meanwhile, directions indicated by the first to third directions DR1, DR2, and DR3 are relative concepts, and may thus be changed to other directions.

The display device ED may be flexible. The term “flexible” indicates a property of being bendable, and may include all from a structure being completely foldable to a structure being bendable up to several nanometers. For example, the flexible display device ED may be a curved device or a foldable device. However, the embodiment of the invention is not limited thereto, and the display device ED may be rigid.

FIG. 1 shows a display device ED having a planar display surface IS as an example. However, the shape of the display surface IS of the display device ED is not limited thereto, and may be a curved shape or a three-dimensional shape in another embodiment.

The display surface IS of the display device ED may include a display portion AA-DD and a non-display portion NAA-DD. The display portion AA-DD may be a portion where the image IM is displayed on the front surface of the display device ED, and users may view the image IM through the display portion AA-DD. Although the present embodiment shows the display portion AA-DD having a rectangular shape when viewed on a plane as an example, the shape of the display portion AA-DD may be variously modified according to the design of the display device ED.

The non-display portion NAA-DD may be a portion where the image IM is not displayed on the front surface of the display device ED. The non-display portion NAA-DD may be a portion having a predetermined color and blocking light. The non-display portion NAA-DD may be positioned adjacent to the display portion AA-DD. In an embodiment, for example, the non-display portion NAA-DD may be disposed outside the display portion AA-DD to surround the display portion AA-DD. However, this is presented as an example, and the non-display portion NAA-DD may be positioned adjacent to only one side of the display portion AA-DD or may be disposed not one a front surface but on a side of the display device ED. In addition, the embodiment of the invention is not limited thereto, and the non-display portion NAA-DD may not be provided in another embodiment.

The display portion AA-DD of the display device ED in an embodiment may include a sensing region SA-DD. The sensing region SA-DD may correspond to a region where an electronic module EM of FIG. 2 overlaps. The electronic module EM (FIG. 2) may receive external inputs delivered through the sensing region SA-DD or output signals through the sensing region SA-DD. FIG. 1 shows one sensing region SA-DD disposed in the display portion AA-DD as an example but is not limited thereto, and a plurality of sensing regions SA-DD may be provided in the display portion AA-DD in another embodiment.

The display device ED of an embodiment may sense external inputs applied from the outside. The external inputs may have various forms such as pressure, temperature, and light provided from the outside. The external inputs may include inputs applied when being in contact (e.g., contact by a user's hand or a pen) with the display device ED, as well as inputs applied when being close to the display device ED such as hovering.

Referring to FIGS. 1 and 2, the display device ED may include a window WP and a housing HU. The window WP may be bonded to the housing HU to form an outer portion of the display device ED, and may provide an inner space for housing components of the display device ED. The display device ED may include a display module DM, a light control member ARP, and an electronic module EM disposed between the window WP and the housing HU.

The electronic module EM may be disposed below the display module DM. The electronic module EM may be disposed to overlap the display module DM in a plan view. The electronic module EM may be an electronic component that outputs or receives optical signals. In an embodiment, for example, the electronic module EM may be a camera module configured to photograph external images. The embodiment of the invention is not limited thereto, and the electronic module EM may be a sensor module such as a proximity sensor or an infrared light emitting sensor in another embodiment.

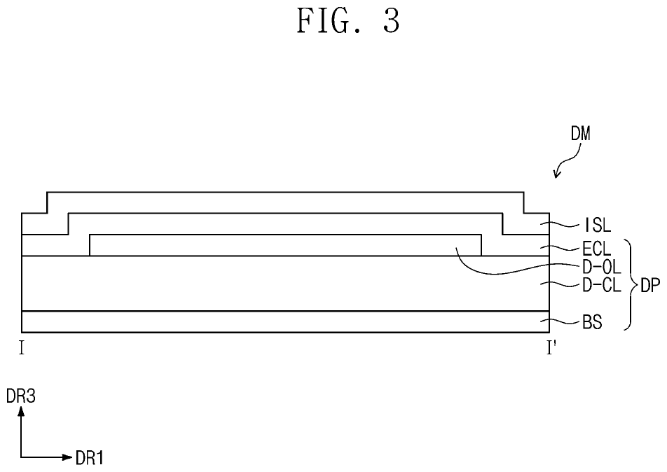

The display module DM may be disposed on the electronic module EM. The display module DM may include a display panel DP (FIG. 3), which will be described later. The display panel DP (FIG. 3) may generate images according to electrical signals. The display panel DP (FIG. 3) may be a light emitting display panel, but is not limited thereto.

The display module DM may include an active region DM-AA and a peripheral region DM-NAA positioned adjacent to the active region DM-AA. The active region DM-AA may be a region activated according to electrical signals. A plurality of pixels PX may be disposed in the active region DM-AA.

The peripheral region DM-NAA may surround the active region DM-AA. The peripheral region DM-NAA may be a region in which driving circuits or driving lines for driving the pixels PX disposed in the active region DM-AA and various signal lines or pads for providing electric signals may be disposed.

The display module DM may include a hole region HA placed in the active region DM-AA. The hole region HA may correspond to the sensing region SA-DD described above. Meanwhile, herein, “a region/portion corresponds to another region/portion” indicates that “the regions/portions overlap each other”, and is not limited to having the same surface area and/or having the same shape. The hole region HA may also be referred to as a first region HA.

The hole region HA may be a region that overlaps the electronic module EM. A hole HH passing through the display module DM may be defined in the hole region HA. The hole HH may overlap the electronic module EM in a plan view. In an embodiment, a portion of the electronic module EM may be inserted into the hole HH.

In FIG. 2, one hole HH having a circular shape is shown as an example, but the embodiment of the invention is not limited thereto. The number of holes HH may be defined in plurality to correspond to the number of electronic modules EM disposed below the display module DM. In addition, the shape of the hole HH may be polygonal or oval when viewed on a plane, and the shape of the hole HH on a plane may be provided in various forms depending on the shape or arrangement of the electronic module EM.

The display device ED may receive external signals for the electronic module EM through the hole region HA, or may provide signals output from the electronic module EM to the outside. According to an embodiment of the invention, the hole region HA is provided in the active region DM-AA, and an area of the non-display portion NAA-DD for disposing the electronic module EM may thus be reduced.

At least a portion of the hole region HA may be surrounded by the display region AA in a plan view. The display region AA may be referred to as a second region. The active region DM-AA of the display module DM of an embodiment may include a hole region HA and a display region AA. In an embodiment, the hole region HA may be entirely surrounded in the display region AA, but is not limited thereto, and a portion of the hole region HA may be surrounded by the display region AA, and the other portion thereof may be surrounded by the peripheral region DM-NAA in another embodiment.

The display device ED may include a light control member ARP disposed between the display module DM and the window WP. The light control member ARP may be a reflection reduction layer that reduces external light reflectance caused by light incident from outside the display device ED. However, the embodiment of the invention is not limited thereto, and the light control member ARP may include various components of the light control layer to improve the display quality of the display device ED. In an embodiment, for example, the light control member ARP of an embodiment may include a polarizing layer, a phase retarder, a destructive interference structure, or a plurality of color filters. Meanwhile, in the display device ED of an embodiment, the light control member ARP may not be provided.

A portion of the light control member ARP overlapping the hole region HA may have relatively high light transmittance. In an embodiment, for example, the light control member ARP may include a transmission portion overlapping the hole region HA, but is not limited thereto, and the light control member ARP may overlap the hole region HA and thus include a hole defined to pass through the light control member ARP in another embodiment.

The window WP may be disposed on the light control member ARP. The window WP may protect the display module DM and the light control member ARP disposed below the window WP.

The window WP may include an optically transparent insulating material. In an embodiment, for example, the window WP may include glass, sapphire, or plastic. The window WP may have a single-layer structure or a multi-layer structure. The window WP may further include functional layers such as an anti-fingerprint layer, a phase control layer, or a hard coating layer disposed on an optically transparent substrate.

A front surface FS of the window WP may correspond to the display surface IS of the display device ED, which is described above. The front surface FS of the window WP may include a transmission region TA and a bezel region BZA.

The transmission region TA of the window WP may be an optically transparent region. The transmission region TA may correspond to the display portion AA-DD of the display device ED. The transmission region TA may overlap at least a portion of the active region DM-AA of the display module DM. The window WP may transmit images provided from the display module DM through the transmission region TA, and users may view the corresponding images.

The transmission region TA of the window WP may include a sensing region SA. The sensing region SA of the window WP may correspond to the sensing region SA-DD of the display device ED. The sensing region SA of the window WP may overlap the hole region HA and the electronic module EM. The sensing region SA of the window WP may have relatively high light transmittance. Accordingly, the electronic module EM may effectively receive external inputs or output signals through the sensing region SA.

The bezel region BZA of the window WP may be a region where a transparent substrate is deposited, coated, or printed with a material having a predetermined color. The bezel region BZA may correspond to the non-display portion NAA-DD of the display device ED. The bezel region BZA may overlap at least a portion of the peripheral region DM-NAA of the display module DM. The bezel region BZA of the window WP covers the peripheral region DM-NAA of the display module DM, and may thus prevent a component of the display module DM disposed in the peripheral region DM-NAA from being viewed to the outside.

The housing HU may be disposed below the display module DM. The housing HU may protect components accommodated in the housing HU. The housing HU may prevent foreign substances or moisture from penetrating into the display module DM and the light control member ARP from the outside. The housing HU may include materials having relatively high rigidity, and the housing HU may absorb shocks applied from the outside. The housing HU may be provided in the form that a plurality of receiving members are combined.

FIG. 3 is a cross-sectional view of a display module according to an embodiment. FIG. 3 is a view schematically showing a cross-section corresponding to line I-I′ of FIG. 2.

Referring to FIG. 3, the display module DM according to an embodiment may include a display panel DP and an input sensor ISL. The display panel DP may include a base layer BS, a circuit layer D-CL, a display element layer D-OL, and an encapsulation layer ECL.

The base layer BS may be a member providing a base surface in which the circuit layer D-CL is disposed. The base layer BS may be a rigid substrate, or a flexible substrate that is bendable, foldable, rollable, or the like. The base layer BS may be a glass substrate, a metal substrate, or a polymer substrate. However, the embodiment of the invention is not limited thereto, and the base layer BS may be an inorganic layer, an organic layer, or a composite material layer in another embodiment.

The circuit layer D-CL may be disposed on the base layer BS. The circuit layer D-CL may include an insulating layer, a semiconductor pattern, a conductive pattern, a signal transmission region, and/or the like. The insulating layer, the semiconductor layer, and the conductive layer may be formed on the base layer BS through methods such as coating or vapor deposition, and then selectively patterned through multiple times of a photolithography process. Then, the semiconductor pattern, the conductive pattern, and the signal line included in the circuit layer D-CL may be formed.

The display element layer D-OL may be disposed on the circuit layer D-CL. The display element layer D-OL may include a light emitting element. In an embodiment, for example, the display element layer D-OL may include organic light emitting materials, inorganic light emitting materials, organic-inorganic light emitting materials, quantum dots, quantum rods, micro LEDs, or nano LEDs.

The encapsulation layer ECL may be disposed on the display element layer D-OL. The encapsulation layer ECL may serve to protect the display element layer D-OL from moisture, oxygen, and foreign substances such as dust particles. The encapsulation layer ECL of an embodiment may include an inorganic polysilazane compound. The inorganic polysilazane compound may be a layer formed when a silazane-based compound is polymerized and cured.

In an embodiment, a barrier layer including the inorganic polysilazane compound may include silicon (Si) and nitrogen (N), and may be a layer including silicon nitride in which Si and N are bonded to form a network. In addition, in an embodiment, a barrier layer including the inorganic polysilazane compound may include Si, oxygen (O), and N, and may be a layer including silicon oxynitride in which Si, O, and N are bonded to form a network.

In an embodiment, the encapsulation layer ECL may include a plurality of layers, and among the plurality of layers, may include an inorganic polysilazane-based compound in a layer spaced apart from the display element layer D-OL and disposed on an uppermost portion of the encapsulation layer ECL. The encapsulation layer ECL according to an embodiment will be described in more detail later.

In the display module DM of an embodiment, an input sensor ISL may be disposed on the encapsulation layer ECL. The input sensor ISL may be formed on the encapsulation layer ECL through a roll-to-roll process. In this case, the input sensor ISL may be indicated as being directly disposed on the encapsulation layer ECL. Being directly disposed may indicate that a third component is not disposed between the input sensor ISL and the encapsulation layer ECL. That is, a separate adhesive member may not be disposed between the input sensor ISL and the encapsulation layer ECL. Alternatively, the input sensor ISL may be bonded to the encapsulation layer ECL through an adhesive member. The adhesive member may include a general adhesive or a gluing agent.

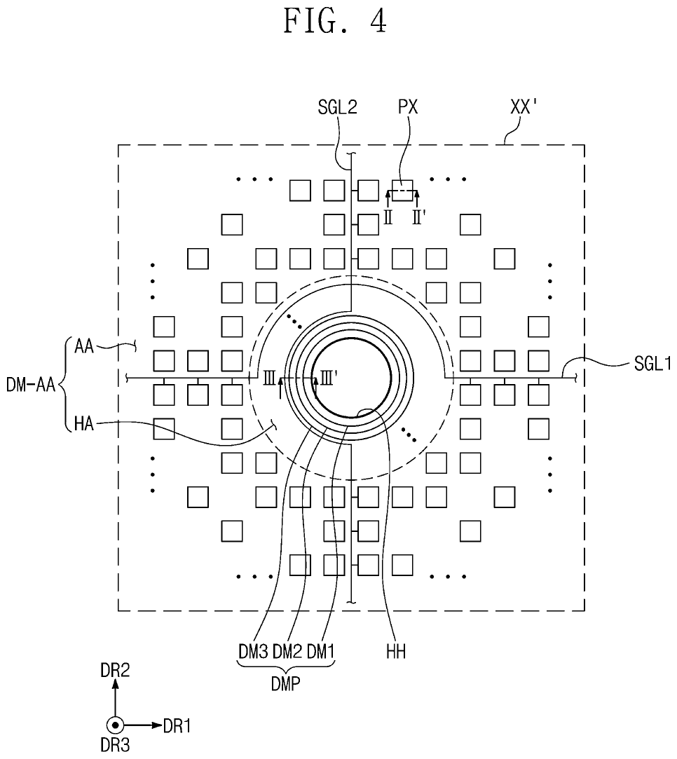

FIG. 4 is a plan view schematically showing a portion of a display module according to an embodiment. FIG. 4 shows region XX′ of FIG. 2, and the region XX′ may be a region corresponding to a portion of the active region DM-AA including the hole HH.

Referring to FIG. 4, a plurality of pixels PX may be disposed in the active region DM-AA of the display module DM. In an embodiment, most of the pixels PX among the plurality of pixels PX may be disposed in the display region AA (or second region) spaced apart from the hole region HA, and some of the pixels PX may be disposed in the display region AA along a border between the hole region HA (or first region) and the display region AA. The pixels PX positioned adjacent to the border of the hole region HA may be disposed spaced apart from the hole HH in a plan view.

A hole HH may be defined in the hole region HA. A hole HH may be defined in the active region DM-AA. Accordingly, at least some of the pixels PX may be disposed adjacent to the hole HH, and the pixels PX may be disposed spaced apart with the hole HH therebetween. The electronic module EM may overlap the hole HH in a plan view.

A dam pattern DMP may be disposed in the hole region HA. The display device ED (FIG. 2) according to an embodiment may block a path through which moisture and/or oxygen flows from the hole HH to the pixels PX by using the dam pattern DMP. The dam pattern DMP may be disposed in the hole region HA and may include at least one dam portion DM1, DM2, and DM3. The dam portions DM1, DM2, and DM3 may each surround at least a portion of the hole HH. According to an embodiment, when viewed on a plane, the dam portions DM1, DM2, and DM3 may each have a closed-line shape surrounding the hole HH.

In an embodiment, a filling material may be further disposed inside the hole HH. The filling material may include a polymer resin. The filling material is disposed inside the hole HH, and may thus provide a flat surface to the configuration placed on the hole HH. In addition, a material that is transparent and has no optical anisotropy may be used as the filling material. The filling material may be used without limitation as long as it does not deteriorate the sensing ability of the electronic module EM (FIG. 2). Meanwhile, the filling material may not be provided.

A portion of each of a plurality of signal lines SGL1 and SGL2 connected to the pixels PX may be disposed in the hole region HA. The signal lines SGL1 and SGL2 are connected to the pixels PX spaced apart with the hole region HA therebetween. For ease of description, FIG. 4 shows two signal lines SGL1 and SGL2 among a plurality of signal lines connected to the pixels PX.

The first signal line SGL1 extends along the first direction DR1. The first signal line SGL1 is connected to pixels PX in the same row arranged along the first direction DR1 among the pixels PX. The first signal line SGL1 is described as corresponding to any one of scan lines connected to the pixels PX as an example.

Some of the pixels PX connected to the first signal line SGL1 are disposed on the left side of the hole HH, and other some pixels PX are disposed on the right side of the hole HH. Accordingly, the pixels PX in the same row, which are connected to the first signal line SGL1 may be turned on/off by substantially the same scan signal even when some pixels are not given around the hole HH.

The second signal line SGL2 extends along the second direction DR2. The second signal line SGL2 is connected to pixels in the same row arranged along the second direction DR2 among the pixels PX. The second signal line SGL2 is described as corresponding to any one of data lines connected to the pixels PX.

Some of the pixels connected to the second signal line SGL2 are disposed above the hole HH, and other some pixels are disposed below the hole HH. Accordingly, the pixels in the same row, which are connected to the second signal line SGL2 may receive data signals through the same line even when some pixels are not given around the hole HH.

At least any one of the first signal line SGL1 or the second signal line SGL2 may be disconnected in the hole region HA at the point where the first signal line SGL1 and the second signal line SGL2 cross, and may further include a connection pattern disposed on a different layer from the disconnected signal line and connecting the disconnected portion. However, the connection relationship between the pixels PX spaced apart with the hole HH therebetween is not limited thereto.

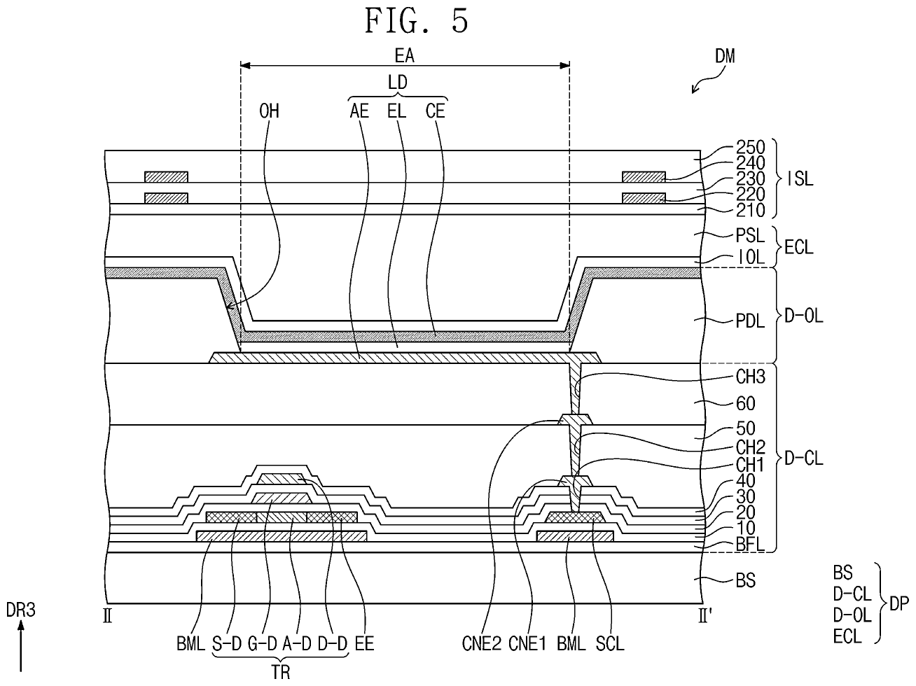

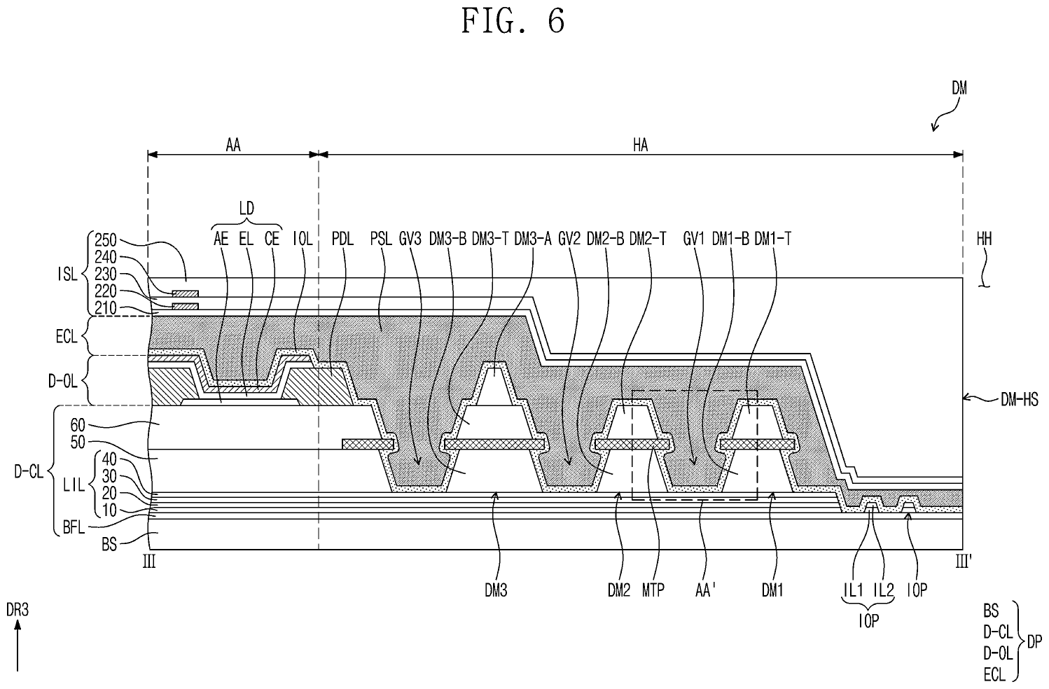

FIGS. 5 and 6 are each cross-sectional views showing a portion of a display module according to an embodiment. FIG. 5 may be a portion corresponding to line II-II′ of FIG. 4, and FIG. 6 may be a portion corresponding to line III-III′ of FIG. 4. FIG. 5 shows a portion of the display region AA (FIG. 4), and FIG. 6 shows a portion of the hole region HA (FIG. 4).

Referring to FIGS. 5 and 6, the display module DM may include a display panel DP and an input sensor ISL, and the display panel DP may include a base layer BS, a circuit layer D-CL, a display element layer D-OL, and an encapsulation layer ECL, which are sequentially stacked.

FIG. 5 shows a portion corresponding to the pixel PX (FIG. 4) described in FIG. 4 as an example. FIG. 5 shows one transistor TR and a light emitting element LD included in the pixel PX (FIG. 4) as an example.

The circuit layer D-CL may include a buffer layer BFL, a shielding electrode BML, a transistor TR, a signal transmission region SCL, a plurality of insulating layers 10, 20, 30, 40, 50, and 60, an upper electrode pattern EE, and a plurality of connection electrodes CNE1 and CNE2. Meanwhile, although not shown, the circuit layer D-CL may further include a plurality of conductive patterns. In an embodiment, for example, the circuit layer D-CL may further include a plurality of transistors, a capacitor, or additional conductive patterns constituting a connection electrode, in addition to the transistor TR shown. Meanwhile, the components of the circuit layer D-CL shown in FIG. 5 are presented as an example, and the type, number, arrangement position of conductive patterns, and the number of insulating layers may be changed.

The buffer layer BFL may be disposed on the base layer BS. The buffer layer BFL may improve the bonding force between the base layer BS and a semiconductor pattern or a conductive pattern disposed on the buffer layer BFL. In addition, the buffer layer BFL may prevent diffusion of metal atoms or impurities from the base layer BS into the semiconductor pattern or the conductive pattern.

The buffer layer BFL may be an inorganic layer. The buffer layer BFL may include at least one of silicon oxide, silicon nitride, or silicon oxynitride. In an embodiment, for example, the buffer layer BFL may include a structure in which a silicon oxide layer and a silicon nitride layer are alternately stacked. In an embodiment, the buffer layer BFL may not be provided.

The shielding electrode BML may be disposed on the buffer layer BFL. The shielding electrode BML may overlap the transistor TR in a plan view. In addition, in an embodiment, the shielding electrode BML may be disposed below the signal transmission region SCL. The shielding electrode BML may block light incident from a lower portion of the display panel DP to the transistor TR or the signal transmission region SCL to protect semiconductor patterns or conductive patterns such as the transistors TR and the signal transmission region SCL. The shielding electrode BML may include a conductive material. When a voltage is applied to the shielding electrode BML, threshold voltage of the transistor TR disposed on the shielding electrode BML may be maintained. The embodiment of the invention is not limited thereto, and the shielding electrode BML may be a floating electrode in another embodiment. In an embodiment, the shielding electrode BML may not be provided.

The circuit layer D-CL may include a plurality of insulating layers 10, 20, 30, 40, 50, and 60, which are sequentially stacked. The insulating layers 10, 20, 30, 40, 50, and 60 may be disposed on the buffer layer BFL. The insulating layers 10, 20, 30, 40, 50, and 60 may be inorganic layers or organic layers. For example, in an embodiment, the first to fourth insulating layers 10, 20, 30, and 40 may include an inorganic film, and the fifth and sixth insulating layers 50 and 60 may include an organic film. However, the embodiment of the invention is not limited thereto. In addition, in the circuit layer D-CL, at least one of the first to sixth insulating layers 10, 20, 30, 40, 50, and 60 may not be provided or an additional insulating layer may be further included in another embodiment.

The first insulating layer 10 may be disposed on the buffer layer BFL. The first insulating layer 10 may include an inorganic film. The first insulating layer 10 may also be referred to as a first inorganic layer. In an embodiment, for example, the first insulating layer 10 may be an inorganic layer include at least one of aluminum oxide, titanium oxide, silicon oxide, silicon nitride, silicon oxynitride, zirconium oxide, or hafnium oxide. The first insulating layer 10 may have a single-layer structure or a multi-layer structure. The first insulating layer 10 may have a structure in which a plurality of inorganic films are stacked.

In addition, in an embodiment, the first insulating layer 10 may further include an organic film in addition to the inorganic film. When the first insulating layer 10 includes a structure in which an inorganic film and an organic film are stacked, the first insulating layer 10 may further include a buffer inorganic film disposed between the inorganic film and the organic film, which are positioned adjacent to each other.

Meanwhile, the content described with respect to the first insulating layer 10 may also apply to the second to fourth insulating layers 20, 30, and 40, which will be described later. The second to fourth insulating layers 20, 30, and 40 may be referred to as second to fourth inorganic films, respectively. The second to fourth insulating layers 20, 30, and 40 may each have a single-layer structure or a multi-layer structure. In an embodiment, for example, the second to fourth insulating layers 20, 30, and 40 may each independently include at least one of silicon oxide, silicon nitride, or silicon oxynitride.

Semiconductor patterns may be disposed on the circuit layer D-CL. The semiconductor patterns may include polysilicon. However, the embodiment of the invention is not limited thereto, and the semiconductor patterns may include amorphous silicon or a metal oxide in another embodiment. The semiconductor patterns may have different electrical properties according to with/without doping. The semiconductor patterns may include a first region having a high doping concentration and a second region having a low doping concentration. The first region may be doped with an N-type dopant or a P-type dopant. A P-type transistor may include the first region doped with a P-type dopant.

The first region has greater conductivity than the second region, and substantially serves as an electrode or a signal line. The second region may substantially correspond to an active (or a channel) of the transistor. That is, a portion of the semiconductor patterns may be an active of the transistor, another portion may be a source or a drain of the transistor, and the other portion may be a conductive region.

Referring to FIG. 5, in an embodiment, the transistor TR may be disposed on the first insulating layer 10. Although not shown, the transistor TR may be electrically connected to the light emitting element LD. A source S-D, an active A-D, and a drain D-D of the transistor TR may be formed from the semiconductor patterns. In addition, FIG. 5 shows a portion of the signal transmission region SCL formed from the semiconductor patterns. The signal transmission region SCL may be disposed on the first insulating layer 10. Meanwhile, although not shown separately, the signal transmission region SCL may be connected to the drain D-D of the transistor TR when viewed on a plane (i.e., plan view).

The second insulating layer 20 may cover the source S-D, the active A-D, the drain D-D, and the signal transmission region SCL of the transistor TR disposed on the first insulating layer 10. A gate G-D of the transistor TR may be disposed on the second insulating layer 20. The third insulating layer 30 may be disposed on the second insulating layer 20 to cover the gate G-D. An upper electrode pattern EE may be disposed on the third insulating layer 30. The fourth insulating layer 40 may be disposed on the third insulating layer 30 to cover the upper electrode pattern EE.

The first connection electrode CNE1 may be disposed on the fourth insulating layer 40. The first connection electrode CNE1 may be connected to the signal transmission region SCL through a contact hole CH1 that passes through the second to fourth insulating layers 20, 30, and 40. The fifth insulating layer 50 may be disposed on the fourth insulating layer 40 to cover the first connection electrode CNE1. The fifth insulating layer 50 may be an organic layer. The fifth insulating layer 50 may be referred to as a first organic film.

The second connection electrode CNE2 may be disposed on the fifth insulating layer 50. The second connection electrode CNE2 may be connected to the first connection electrode CNE1 through a contact hole CH2 that passes through the fifth insulating layer 50. The sixth insulating layer 60 may be disposed on the fifth insulating layer 50 to cover the second connection electrode CNE2. The sixth insulating layer 60 may be an organic layer. The sixth insulating layer 60 may be referred to as a second organic film.

The fifth insulating layer 50 and the sixth insulating layer 60 may include at least any one of an acryl-based resin, a methacrylate-based resin, a polyisoprene-based resin, a vinyl-based resin, an epoxy-based resin, a urethane-based resin, a cellulose-based resin, a siloxane-based resin, a polyamide-based resin, or a perylene-based resin.

The display element layer D-OL may be disposed on the circuit layer D-CL. The display element layer D-OL may include the light emitting element LD and a pixel defining film PDL. The light emitting element LD may include a first electrode AE, a second electrode CE facing the first electrode AE, and a functional layer EL disposed between the first electrode AE and the second electrode CE.

A light emitting opening OH exposing a portion of an upper surface of the first electrode AE may be defined in the pixel defining film PDL. A light emitting region EA may be defined to correspond to the light emitting opening OH.

The first electrode AE may be disposed on the circuit layer D-CL. In an embodiment, the first electrode AE may be disposed on the sixth insulating layer 60 of the circuit layer D-CL. The first electrode AE may be connected to the second connection electrode CNE2 through a connection contact hole CH3 defined through the sixth insulating layer 60. Accordingly, the first electrode AE may be electrically connected to the signal transmission region SCL through the first and second connection electrodes CNE1 and CNE2 and electrically connected to a corresponding circuit element. The first electrode AE may include a single-layer structure or a multi-layer structure.

The first electrode AE may be an anode or cathode. In addition, the first electrode AE may be a pixel electrode. The second electrode CE may be a cathode or an anode. The second electrode CE may be a common electrode. In an embodiment, for example, when the first electrode AE is an anode, the second electrode CE may be a cathode, and when the first electrode AE is a cathode, the second electrode CE may be an anode.

The first electrode AE may be a transmissive electrode, a transflective electrode, or a reflective electrode. The first electrode AE may include Ag, Mg, Cu, Al, Pt, Pd, Au, Ni, Nd, Ir, Cr, Li, Ca, LiF/Ca, LiF/Al, Mo, Ti, W, a compound thereof, or a mixture thereof (e.g., a mixture of Ag and Mg). Alternatively, the first electrode AE may have a multilayer structure including a reflective film or a transflective film formed of or including the above-described materials, and a transparent conductive film formed of or including indium tin oxide (“ITO”), indium zinc oxide (“IZO”), zinc oxide (ZnO), indium tin zinc oxide (“ITZO”), and/or the like. In an embodiment, for example, the first electrode AE may have a three-layer structure of ITO/Ag/ITO, but is not limited thereto. In addition, the embodiment of the invention is not limited thereto, and the first electrode AE may include the above-described metal materials, a combination of two or more metal materials selected from the above-described metal materials, or oxides of the above-described metal materials in another embodiment.

The second electrode CE may be a transmissive electrode, a transflective electrode, or a reflective electrode. When the second electrode CE is a transmissive electrode, the second electrode CE may be formed of or include a transparent metal oxide, for example, indium tin oxide (ITO), indium zinc oxide (IZO), zinc oxide (ZnO), indium tin zinc oxide (ITZO), and/or the like. In addition, the second electrode CE may be formed including Ag, Mg, Cu, Al, Pt, Pd, Au, Ni, Nd, Ir, Cr, Li, Ca, LiF/Ca, LiF/Al, Mo, Ti, W, a compound thereof, or a mixture thereof (e.g., a mixture of Ag and Mg).

The functional layer EL may include an emission layer. The emission layer may include a light emitting material such as an organic material or quantum dots. The functional layer EL including the emission layer may emit light of at least one among blue, red, or green in separate pixels. Meanwhile, in an embodiment, the functional layer EL may provide blue light throughout the active region DM-AA (FIG. 4).

The functional layer EL may further include a hole control layer and an electron control layer in addition to the emission layer. The hole control layer may be disposed between the first electrode AE and the emission layer, and the electron control layer may be disposed between the emission layer and the second electrode CE.

Among the functional layers EL, the emission layer may be patterned and provided to correspond to the light emitting region EA. In addition, among the functional layers EL, the hole control layer and the electron control layer may be commonly disposed in the plurality of pixels PX (FIG. 4). That is, the hole control layer and the electron control layer may be provided as common layers throughout the pixels PX (FIG. 4). However, the embodiment of the invention is not limited thereto, and the hole control layer and the electron control layer may be patterned and provided to correspond to the light emitting region EA, or may be provided in a form in which a portion thereof is short-circuited by overlapping the pixel defining film PDL in another embodiment.

In an embodiment, the pixel defining film PDL may have a single-layer structure or a multi-layer structure. The pixel defining film PDL may be formed of or include a polymer resin. In an embodiment, for example, the pixel defining film PDL may include a polyacrylate-based resin or a polyimide-based resin. In addition, the pixel defining film PDL may be formed by further including an inorganic material in addition to the polymer resin. Meanwhile, the pixel defining film PDL may be formed including a light absorbing material, or may be formed including a black pigment or a black dye. The pixel defining film PDL formed including a black pigment or a black dye may implement a black pixel defining film. When forming the pixel defining film PDL, carbon black may be used as a black pigment or a black dye, but the embodiment of the invention is not limited thereto.

In addition, the pixel defining film PDL may be formed of or include an inorganic material. In an embodiment, for example, the pixel defining film PDL may be formed of or include silicon nitride (SiNx), silicon oxide (SiOx), silicon oxynitride (SiOxNy), or the like.

The encapsulation layer ECL may be disposed on the second electrode CE of the light emitting element LD. The encapsulation layer ECL may cover the light emitting element LD. In an embodiment, the encapsulation layer ECL may include an inorganic encapsulation film IOL and a barrier layer PSL. In an embodiment, the encapsulation layer ECL may not include an organic encapsulation film formed of or including an organic material.

The input sensor ISL may be disposed on the display panel DP. The input sensor ISL may be directly disposed on the barrier layer PSL. The input sensor ISL may include a sensor base layer 210, a first sensor conductive layer 220, a sensor insulating layer 230, a second sensor conductive layer 240, and a sensor cover layer 250.

The sensor base layer 210 may be directly disposed on the display panel DP. The sensor base layer 210 may be an inorganic layer including at least any one among silicon nitride, silicon oxynitride, and silicon oxide. Alternatively, the sensor base layer 210 may be an organic layer including an epoxy resin, an acrylic resin, or an imide-based resin. The sensor base layer 210 may have a single layer structure or may have a multilayer structure stacked along the third direction DR3.

The first sensor conductive layer 220 and the second sensor conductive layer 240 may each have a single-layer structure or may have a multi-layer structure stacked along the third direction DR3.

The single-layer conductive layer may include a metal layer or a transparent conductive layer. The metal layer may include molybdenum, silver, titanium, copper, aluminum, or an alloy thereof. The transparent conductive layer may include a transparent conductive oxide such as indium tin oxide, indium zinc oxide, zinc oxide, or indium zinc tin oxide. In addition, the transparent conductive layer may include a conductive polymer such as poly(3,4-ethylenedioxythiophene) (“PEDOT”), a metal nanowire, and graphene.

The conductive layer having a multi-layer structure may include metal layers. The metal layers may have a three-layer structure of, for example, titanium/aluminum/titanium. The multi-layer conductive layer may include at least one metal layer and at least one transparent conductive layer.

The sensor insulating layer 230 may be disposed between the first sensor conductive layer 220 and the second sensor conductive layer 240. The sensor cover layer 250 may be disposed on the sensor insulating layer 230 and may cover the second sensor conductive layer 240. The second sensor conductive layer 240 may include a conductive pattern. The sensor cover layer 250 may cover the conductive pattern and reduce or eliminate the probability of damage to the conductive pattern in a subsequent process.

The sensor insulating layer 230 and the sensor cover layer 250 may each include an inorganic film. The inorganic film may include at least one of aluminum oxide, titanium oxide, silicon oxide, silicon nitride, silicon oxynitride, zirconium oxide, or hafnium oxide.

Alternatively, the sensor insulating layer 230 and the sensor cover layer 250 may each include an organic film. The organic film may include at least any one of an acryl-based resin, a methacrylate-based resin, polyisoprene, a vinyl-based resin, an epoxy-based resin, a urethane-based resin, a cellulose-based resin, a siloxane-based resin, a polyimide-based resin, a polyamide-based resin, or a perylene-based resin.

Referring to FIGS. 4 and 6, a hole HH is defined in the display module DM, and the display module DM may include a hole region HA including the hole HH formed through the display module DM. The hole HH is formed through the display module DM and may be defined by a sidewall DM-HS of the display module DM, which is exposed.

The display module DM may include a plurality of dam portions DM1, DM2, and DM3 disposed in the hole region HA. The dam portions DM1, DM2, and DM3 may protect the display element layer D-OL during the process of forming the hole HH. In an embodiment, for example, the dam portions DM1, DM2, and DM3 may prevent physical shock, such as cracks, which may take place in the forming of the hole HH from being delivered to the display region AA. In addition, the dam portions DM1, DM2, and DM3 may prevent chemical materials used in processing the display module DM, such as forming the hole HH, from penetrating into the display region AA. In addition, the dam portions DM1, DM2, and DM3 may serve to prevent the flow of a resin composition when an excessive amount of the resin composition is provided when the barrier layer PSL is formed.

Meanwhile, FIGS. 4 and 6 show that three dam portions DM1, DM2, and DM3 are shown, but the embodiment of the invention is not limited thereto. The number of dam portions may be 2 or less or 4 or more in another embodiment.

The dam portions DM1, DM2, and DM3 may be disposed on the base layer BS. In an embodiment, the dam portions DM1, DM2, and DM3 may be disposed on a lower insulating layer LIL. The lower insulating layer LIL may include the first to fourth insulating layers 10, 20, 30, and 40 described in FIG. 5.

An embodiment may include a first dam portion DM1 disposed surrounding the hole HH, and a second dam portion DM2 disposed surrounding the first dam portion DM1 in a plan view. In addition, in an embodiment, the display module DM may further include a third dam portion DM3 surrounding the second dam portion DM2 in a plan view and positioned adjacent to the display region AA.

Grooves GV1, GV2, and GV3 may be defined between the dam portions DM1, DM2, and DM3. The first groove GV1 may be defined between the first dam portion DM1 and the second dam portion DM2, and the second groove GV2 may be defined between the second dam portion DM2 and the third dam portion DM3. In the display module DM of an embodiment shown in FIG. 6, the third groove GV3 may be defined between the third dam portion DM3 and a portion of the display panel DP at a border between the display region AA and the hole region HA.

The dam portions DM1, DM2, and DM3 may each include a plurality of dam layers stacked in the third direction DR3, which is the thickness direction. The first dam portion DM1 and the second dam portion DM2 may each include first dam layers DM1-B and DM2-B and second dam layers DM1-T and DM2-T. The second dam layers DM1-T and DM2-T may be disposed on the first dam layers DM1-B and DM2-B.

The first dam layers DM1-B and DM2-B may be disposed on the same layer as the fifth insulating layer 50, and the second dam layers DM1-T and DM2-T may be disposed on the same layer as the sixth insulating layer 60. In an embodiment, for example, the first dam layers DM1-B and DM2-B may be formed in the same process step along with the first organic film 50, and the second dam layers DM1-T and DM2-T may be formed in the same process step along with the second organic film 60. Specifically, in an embodiment, the first dam layers DM1-B and DM2-B may be organic layers formed of or including the same material as the first organic film 50, and the second dam layers DM1-T and DM2-T may be organic layers formed of or including the same material as the second organic film 60. However, the embodiment of the invention is not limited thereto.

In FIG. 6 and elsewhere, the first dam portion DM1 and the second dam portion DM2 are each shown to include two dam layers, but the embodiment of the invention is not limited thereto, and at least one of the first dam portion DM1 or the second dam portion DM2 may include three dam layers or may include only one dam layer in another embodiment.

Meanwhile, in an embodiment, the third dam portion DM3 may include a first dam layer DM3-B, a second dam layer DM3-T, and a third dam layer DM3-A, which are stacked in the third direction DR3. In the third dam portion DM3, the first dam layers DM3-B and DM2-B may be formed in the same process step along with the first organic film 50, the second dam layer DM3-T may be formed in the same process step along with the second organic film 60, and the third dam layer DM3-A may be formed in the same process step along with the pixel defining film PDL. However, the embodiment of the invention is not limited thereto.

In an embodiment, the first dam layers DM1-B, DM2-B, and DM3-B and the second dam layers DM1-T, DM2-T, and DM3-T may each have inclined sides. However, the embodiment of the invention is not limited thereto, and unlike what is shown, the first dam layers DM1-B, DM2-B, and DM3-B and the second dam layers DM1-T, DM2-T, and DM3-T may each be independently formed to have at least some curved surfaces.

The dam portions DM1, DM2, and DM3 may further include a conductive pattern MTP. The dam portions DM1, DM2, and DM3 may include a conductive pattern MTP disposed between the first dam layers DM1-B, DM2-B, and DM3-B and the second dam layers DM1-T, DM2-T, and DM3-T, and including a protruding portion with a width greater than a width in one direction of the first dam layer DM1-B, DM2-B, and DM3-B.

The conductive pattern MTP may be formed in the same process along with any one of the conductive patterns of the circuit layer D-CL disposed in the display region AA. In an embodiment, for example, the conductive pattern MTP may be formed in the same process step along with the second connection electrode CNE2. Specifically, the conductive pattern MTP may be formed of or include the same material as the second connection electrode CNE2. However, the embodiment of the invention is not limited thereto.

The display module DM may further include inorganic dams IOP disposed in the hole region HA. In FIG. 6 and elsewhere, two inorganic dams IOP disposed adjacent to the hole HH are shown, but the embodiment of the invention is not limited thereto, and at least one of the inorganic dams IOP may not be provided, or more inorganic dams may be disposed in another embodiment.

In an embodiment, the inorganic dams IOP may each include a first layer IL1 and a second layer IL2. The first layer IL1 may include the same material as the first insulating layer 10 and may be formed through the same process along with the first insulating layer 10. The second layer IL2 may include the same material as the second insulating layer 20 and may be formed through the same process along with the second insulating layer 20. However, this is presented only as an example, and the components of the layers constituting each inorganic dam IOP may be variously modified. The first layer IL1 may have a greater width than the second layer IL2. In an embodiment, the inorganic dams IOP may each have a stepped shape.

Referring to FIGS. 5 and 6, the encapsulation layer ECL covers the display element layer D-OL and exposed components of the circuit layer D-CL. In the display region AA, the encapsulation layer ECL covers the light emitting element LD and the pixel defining film PDL, and in the hole region HA, the encapsulation layer ECL covers an exposed portion of the display element layer D-OL, an exposed portion of the circuit layer D-CL, and the dam portions DM1, DM2, and DM3.

The inorganic encapsulation film IOL of the encapsulation layer ECL may be disposed on the second electrode CE. In addition, the inorganic encapsulation film IOL may be disposed on the dam portions DM1, DM2, and DM3 and the grooves GV1, GV2, and GV3. The inorganic encapsulation film IOL may protect components of the display panel DP from moisture and oxygen outside the display panel DP.

The inorganic encapsulation film IOL may be formed through chemical vapor deposition (“CVD”). The inorganic encapsulation film IOL may include a silicon nitride layer, a silicon oxy nitride layer, a silicon oxide layer, a titanium oxide layer, or an aluminum oxide layer.

The encapsulation layer ECL may include a barrier layer PSL directly disposed on the inorganic encapsulation film IOL. The barrier layer PSL is directly disposed on the inorganic encapsulation film IOL and may exhibit excellent adhesion to the inorganic encapsulation film IOL. The barrier layer PSL may include an inorganic polysilazane compound. The barrier layer PSL is formed through polymerization and curing processes after providing a silazane-based compound directly on the inorganic encapsulation film IOL, and may thus have a sufficient thickness to cover the inorganic encapsulation film IOL formed by following a lower step.

The barrier layer PSL may have a thickness of 1,000 Å to 100,000 Å. The barrier layer PSL is provided to have a thickness of 1,000 Å or greater and may thus effectively protect the components of the display panel DP. In addition, according to a method for manufacturing a display device, which will be described later, the barrier layer PSL may be formed using inkjet printing and laser curing, and in this case, the barrier layer PSL may be formed to have a maximum thickness of 100,000 Å or less.

The barrier layer PSL formed to have a sufficient thickness may sufficiently cover the components of the light emitting element LD disposed in the light emitting opening OH. Accordingly, the barrier layer PSL may protect the functional layer EL by sufficiently covering the components of the light emitting element LD disposed in the light emitting opening OH. In addition, the barrier layer PSL formed to have a sufficient thickness fills the grooves GV1, GV2, and GV3 in the hole region HA, and may thus effectively protect the components of the display panel DP and the dam portions DM1, DM2, and DM3 exposed in the hole region HA.

The barrier layer PSL may include an inorganic polysilazane compound. The barrier layer PSL may include an inorganic polymer layer containing Si and N, or an inorganic polymer layer containing Si, N, and O. In an embodiment, for example, the barrier layer PSL may include silicon nitride or silicon oxynitride.

The barrier layer PSL may be formed from a compound having a repeating unit represented by Formula 1 below:

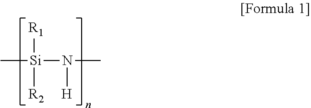

In Formula 1 above, R₁ and R₂ may each independently be a hydrogen atom, an alkyl group having 1 to 10 carbon atoms, or an aryl group having 6 to 30 ring-forming carbon atoms, and n may be an integer of 2 or greater.

In an embodiment, for example, the silazane-based compound having a repeating unit of Formula 1 above may have a structure of Formula 2 below. However, this is presented as an example, and the embodiment of the invention is not limited thereto:

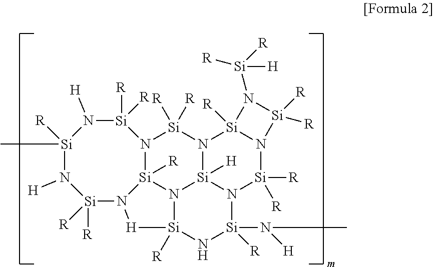

In Formula 2, R may be a hydrogen atom, an alkyl group having 1 to 10 carbon atoms, or an aryl group having 6 to 30 ring-forming carbon atoms, and m may be an integer of 2 or greater.

The silazane-based compound represented by Formula 2 may be referred to as perhydropolysilazane (“PHPS”). That is, in an embodiment, the barrier layer PSL may include inorganic polysilazane formed from PHPS.

In an atmosphere (air) having a specified composition, repeating units of Formula 1 may be randomly combined to form an inorganic polymer layer containing Si and N, or an inorganic polymer layer containing Si, N, and O. Accordingly, the barrier layer PSL may include an inorganic polymer layer containing Si and N, or an inorganic polymer layer containing Si, N, and O.

The barrier layer PSL containing an inorganic polysilazane compound may replace the stack structure of an organic encapsulation film and an upper inorganic encapsulation film in the components of a typical encapsulation layer. That is, the process of forming the encapsulation layer ECL may be simplified in the manufacture of the display panel DP by replacing the stack structure of an organic encapsulation film and an upper inorganic encapsulation film with a single barrier layer PSL containing a silazane-based compound. In addition, as for typical display devices, an additional process of removing an organic encapsulation film after forming the organic encapsulation film in some regions is desirable to form a bond between a lower inorganic encapsulation film and an upper inorganic encapsulation film so as to obtain reliability. However, as for the display device of an embodiment, the barrier layer PSL containing an inorganic polysilazane compound is directly disposed on the inorganic encapsulation film IOL to form a bond between the inorganic layers without an additional process, thereby achieving improved process economic efficiency and excellent reliability.

The barrier layer PSL may have a refractive index of about 1.59 to about 1.90. In an embodiment, the barrier layer PSL is formed including a silazane-based compound and has a relatively greater density than an organic film, and accordingly, the barrier layer PSL including a silazane-based compound may exhibit a greater refractive index value than the organic film.

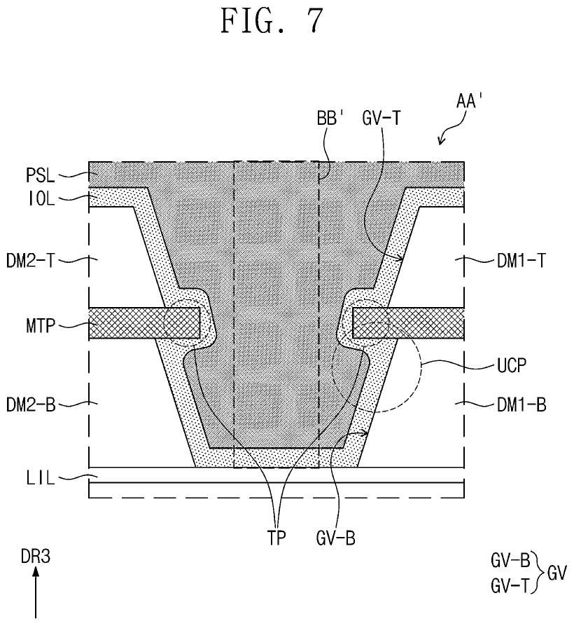

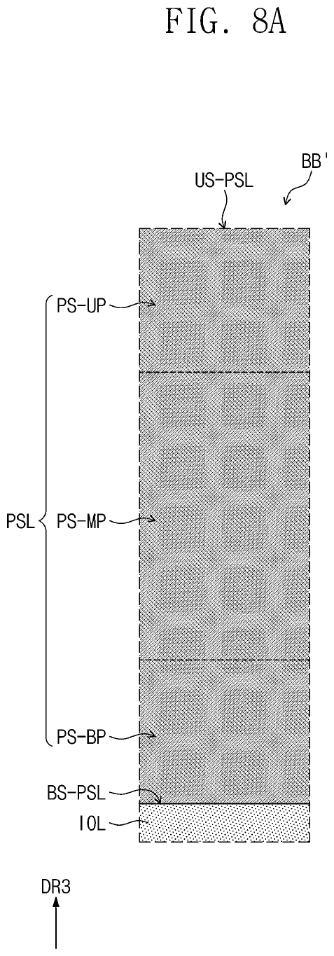

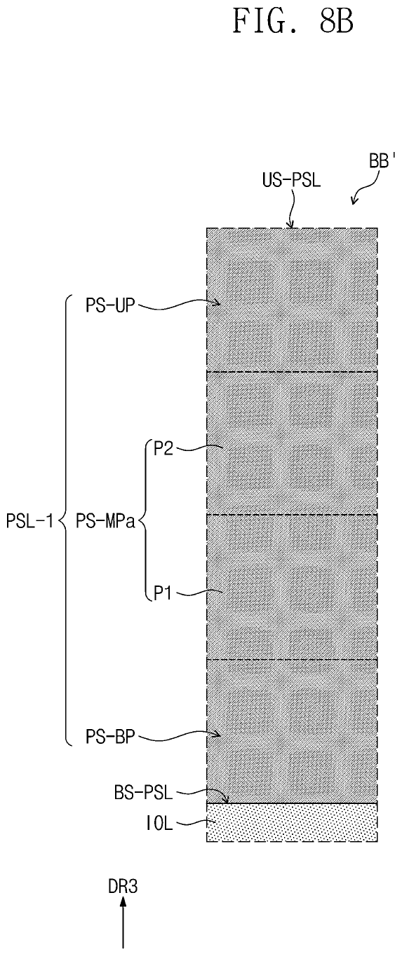

FIG. 7 is a cross-sectional view enlarging region AA′ of FIG. 6. FIGS. 8A and 8B are each views showing a barrier layer according to an embodiment. FIGS. 8A and 8B may each show a portion corresponding to region BB′ of FIG. 7.

Referring to FIGS. 6 and 7, the dam portions DM1, DM2, and DM3 may include a conductive pattern MTP including a tip portion TP, which is a protruding portion. The tip portion TP may be a portion that protrudes in a direction toward the inside of the grooves GV1, GV2, and GV3 or in a direction away from the grooves GV1, GV2, and GV3. The conductive pattern MTP overlaps the entirety of the second dam layers DM1-T, DM2-T, and DM3-T in a plan view, and may have a width greater than a width of one side of an adjacent dam layer in one direction (i.e., a horizontal direction). Meanwhile, the embodiment of the invention is not limited thereto, and the conductive pattern MTP may not overlap the entirety of the second dam layers DM1-T, DM2-T, and DM3-T in a plan view, and may be separated into two portions on a cross-section to be adjacent to edges of the second dam layers DM1-T, DM2-T, and DM3-T positioned adjacent to the grooves GV1, GV2, and GV3 in another embodiment. Meanwhile, the shape of the conductive pattern MTP may be provided in various forms through a method of patterning the dam portions DM1, DM2, and DM3, or a process of patterning the dam portions DM1, DM2, and DM3.

The conductive pattern MTP may be disposed to protrude further inside the groove GV than upper surfaces of the first dam layers DM1-B and DM2-B and lower surfaces of the second dam layers DM1-T and DM2-T, and accordingly, the dam portions DM1 and DM2 may include an undercut portion UCP.

Referring to FIGS. 6 and 7, grooves GV1 and GV2 may be defined between two neighboring dam portions DM1, DM2, and DM3, and the grooves GV1 and GV2 may include a first concave portion GV-B defined by the first dam layers DM1-B and DM2-B and a second concave portion GV-T defined by the second dam layers DM1-T and DM2-T. The second concave portion GV-T may overlap the first concave portion GV-B and thus be defined on the first concave portion GV-B in a plan view.

The inorganic encapsulation film IOL may be disposed to cover an upper surface of the lower insulating layer LIL, a side surface of the first dam layers DM1-B and DM2-B, the tip portion TP of the conductive pattern, and side and upper surfaces of the second dam layers DM1-T and DM2-T, which are exposed in the groove GV. The inorganic encapsulation film IOL disposed around the tip portion TP may not have a uniform thickness due to the undercut portion UCP.

The barrier layer PSL may be disposed to fill the groove GV. The barrier layer PSL may be disposed to fill the entire portion of the first concave portion GV-B and the second concave portion GV-T.

Even in the undercut portion UCP where the inorganic encapsulation film IOL is relatively thin, the barrier layer PSL is bonded to the inorganic encapsulation film IOL and is provided to have a sufficient thickness, and accordingly, the components of the dam portions DM1 and DM2 may be effectively protected by the encapsulation layer ECL. That is, the barrier layer PSL forms an inorganic layer bond with the inorganic encapsulation film IOL, and the film density of the encapsulation layer ECL may thus increase to suppress the penetration of moisture/oxygen or chemical substances.

FIG. 8A is a cross-sectional view showing a portion of the barrier layer PSL according to an embodiment. In an embodiment, the barrier layer PSL may include portions which are different in refractive index. A refractive index at the first portion PS-BP positioned adjacent to the inorganic encapsulation film IOL may be smaller than a refractive index at the second portion PS-UP spaced apart from the inorganic encapsulation film IOL.

In an embodiment, the barrier layer PSL may have a refractive index increasing in a direction away from the inorganic encapsulation film IOL. The refractive index of the barrier layer PSL gradually increases in the direction away from the inorganic encapsulation film IOL, or a refractive index value is similar within a specified thickness range, and a refractive index value outside the specified thickness range may change in phases to have a value distinct from the refractive index value within the specified thickness range.

In an embodiment shown in FIG. 8A, the first portion PS-BP including a lower surface BS-PSL positioned adjacent to the inorganic encapsulation film IOL of the barrier layer PSL may have a first refractive index value, the second portion PS-UP including an upper surface US-PSL may have a second refractive index value greater than the first refractive index, and the third portion PS-MP disposed between the first portion PS-BP and the second portion PS-UP may have a third refractive index value that is a value between the first refractive index and the second refractive index.

In addition, referring to FIG. 8B, a barrier layer PSL-1 according to an embodiment may include portions having four distinct refractive index values. Compared to the barrier layer PSL of an embodiment shown in FIG. 8A, the barrier layer PSL-1 of FIG. 8B may include two sub portions P1 and P2 in which a third portion PS-MPa has different refractive index values. In the third portion PS-MPa, the second sub portion P2 may have a greater refractive index than the first sub portion P1.

In an embodiment shown in FIG. 8A, when the barrier layer PSL is a layer containing silicon nitride, the first portion PS-BP may have a refractive index of about 1.53 to about 1.55, the third portion PS-MP may have a refractive index of about 1.54 to about 1.80, and the second portion PS-UP may have a refractive index of about 1.80 or greater. In addition, in an embodiment shown in FIG. 8A, when the barrier layer PSL is a layer containing silicon oxynitride, the first portion PS-BP may have a refractive index of about 1.53 to about 1.55, the third portion PS-MP may have a refractive index of about 1.54 to about 1.68, and the second portion PS-UP may have a refractive index of about 1.68 or greater.

In an embodiment shown in FIG. 8B, when the barrier layer PSL-1 is a layer containing silicon nitride, the first portion PS-BP may have a refractive index of about 1.53 to about 1.55, the first sub portion P1 and the second sub portion P2 of the third portion PS-MPa may have a refractive index of about 1.54 to about 1.70 and a refractive index of about 1.70 to about 1.80, respectively, and the second portion PS-UP may have a refractive index of about 1.80 or greater. In addition, in an embodiment shown in FIG. 8B, when the barrier layer PSL-1 is a layer containing silicon oxynitride, the first sub portion P1 and the second sub portion P2 of the third portion PS-MPa may have a refractive index of about 1.54 to about 1.60 and a refractive index of about 1.60 to about 1.68, respectively, and the second portion PS-UP may have a refractive index of about 1.68 or greater.

Meanwhile, in FIGS. 8A and 8B, the thicknesses of respective portions having distinct refractive index values are shown to be similar, but the embodiment of the invention is not limited thereto. The thicknesses of the first portion PS-BP and the second portion PS-UP may be relatively thin, and the thicknesses of the third portions PS-MP and PS-MPa may be thicker than the other portions.

In the barrier layers PSL and PSL-1 of an embodiment, the first portion PS-BP may be a silazane-based compound layer including the silazane-based repeating unit of Formula 1 described above. That is, the first portion PS-BP may be a layer containing silazane-based units with low degree of polymerization. The first portion PS-BP may be a layer containing silazane-based units without forming silicon nitride or silicon oxynitride.

Meanwhile, when the entire thickness of the barrier layers PSL and PSL-1 is 3,000 Å or less, a layer (e.g., PS-BP) containing silazane-based units and having a refractive index of about 1.55 or less may not be provided. For example, when the thickness of the entire barrier layers PSL and PSL-1 is 3,000 Å or less, the barrier layers PSL and PSL-1 may be layers containing silicon nitride and a plurality of portions having a refractive index increasing in the thickness direction (i.e., a direction away from the inorganic encapsulation film IOL), or the barrier layers PSL and PSL-1 may be a layer containing silicon oxynitride and a plurality of portions having a refractive index increasing in the thickness direction (i.e., a direction away from the inorganic encapsulation film IOL). In addition, when the thickness of the entire barrier layers PSL and PSL-1 is less than 3,000 Å, the barrier layers PSL and PSL-1 may be a single silicon nitride layer having a single composition and a similar refractive index range, or may be a single silicon oxynitride layer having a single composition and a similar refractive index range.

In the barrier layers PSL and PSL-1 of an embodiment, the second portion PS-UP may be a layer containing only silicon nitride or a layer containing only silicon oxynitride. Meanwhile, in an embodiment, the second portion PS-UP having a refractive index of about 1.80 or greater and containing silicon nitride may not be provided, or in an embodiment, the second portion PS-UP having a refractive index of about 1.68 or greater and containing silicon oxynitride may not be provided.

Meanwhile, in an embodiment, only one portion PS-MP having a similar refractive index value of the barrier layers PSL and PSL-1 may be present. In addition, in an embodiment, in the barrier layers PSL and PSL-1, the upper surface US-PSL may have greater refractive index than the lower surface BS-PSL.

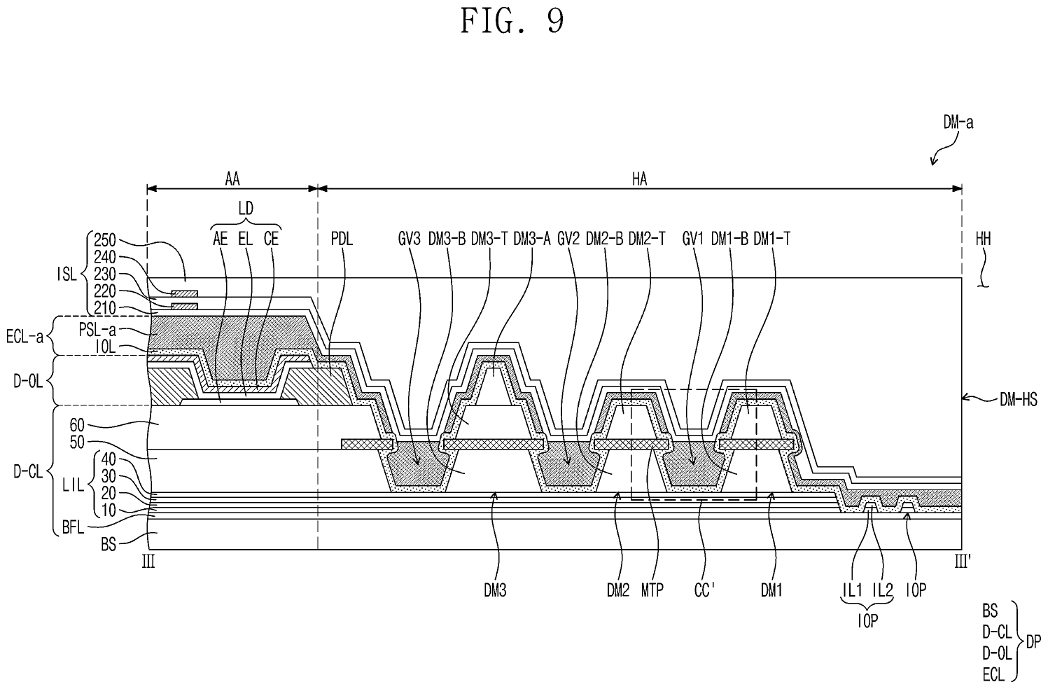

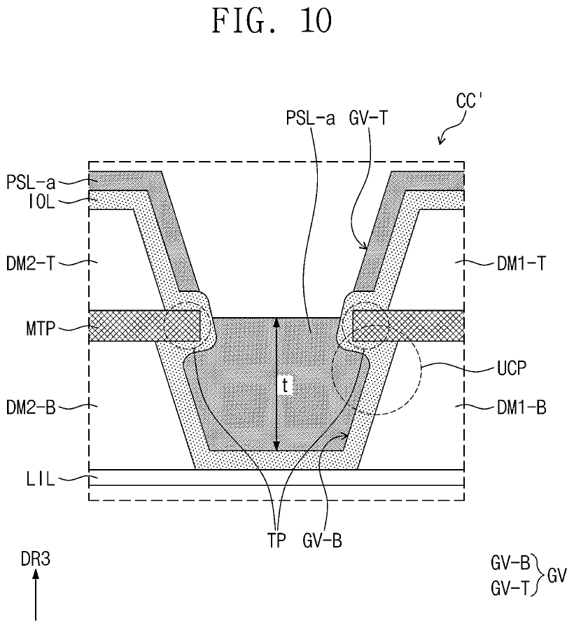

FIG. 9 is a cross-sectional view of a display module according to another embodiment. FIG. 10 is a cross-sectional view enlarging region CC′ of FIG. 9. A display module DM-a according to an embodiment shown in FIG. 9 is different from the display module DM according to an embodiment described with reference to FIGS. 6 and 7 in the shape of the encapsulation layer ECL-a.

In an embodiment, the encapsulation layer ECL-a may include an inorganic encapsulation film IOL and a barrier layer PSL-a directly disposed on the inorganic encapsulation film IOL. The barrier layer PSL-a may include an inorganic polysilazane compound. The descriptions of the barrier layers PSL and PSL-1 described with reference to FIGS. 6 to 8B may also apply to the barrier layer PSL-a, except for the arrangement form.

The inorganic encapsulation film IOL may cover the light emitting element LD and the pixel defining film PDL in the display region AA, and may cover a portion of the circuit layer D-CL, a portion of the display element layer D-OL, the dam portions DM1, DM2, and DM3, and the grooves GV1, GV2, and GV3, which are exposed in the hole region HA.

The barrier layer PSL-a may be disposed on the inorganic encapsulation film IOL and be disposed to fill a portion of the grooves GV1, GV2, and GV3. Referring to FIG. 10, the barrier layer PSL-a may fill a first concave portion GV-B of the groove GV. In an embodiment, the barrier layer PSL-a may cover a lower surface of the tip portion TP of the conductive pattern MTP at the undercut portion UCP. That is, in a portion where the thickness of the inorganic encapsulation film IOL is not uniform, the barrier layer PSL-a may sufficiently cover the first concave portion GV-B and may cover a border between the conductive pattern MTP and the first dam layers DM1-B and DM2-B. Accordingly, the border between the conductive pattern MTP and the first dam layers DM1-B and DM2-B, which is exposed by the tip portion TP is sufficiently protected by the barrier layer PSL-a, and accordingly, the display module DM-a may exhibit excellent reliability.

A thickness t of the barrier layer PSL-a filling the groove GV may be greater than or equal to the thickness of the first dam layers DM1-B and DM2-B. In an embodiment, for example, the thickness t of the barrier layer PSL-a disposed in the groove GV may be 1 micrometer (m) or greater. However, the embodiment of the invention is not limited thereto.

The barrier layer PSL-a may be disposed on the inorganic encapsulation film IOL in a second concave portion GV-T. In an embodiment shown in FIGS. 9 and 10, a portion of the inorganic encapsulation film IOL covering the tip portion TP may not be covered by the barrier layer PSL-a and be exposed. However, the embodiment of the invention is not limited thereto, and the inorganic encapsulation film IOL may be entirely covered with the barrier layer PSL-a in another embodiment.

A display device according to an embodiment including a barrier layer containing an inorganic polysilazane compound may exhibit excellent reliability. As a result of evaluating the water vapor transmission rate (“WVTR”) in the barrier layer formed including a polysilazane compound, the WVTR was found to be less than 10-4 g/m²/day (when the barrier layer has a thickness of about 2000 Å or greater), and this indicates that excellent reliability may be achieved when the barrier layer is provided to have a thickness greater than or equal to a thickness of the first dam layer, which is a lower portion of the dam.

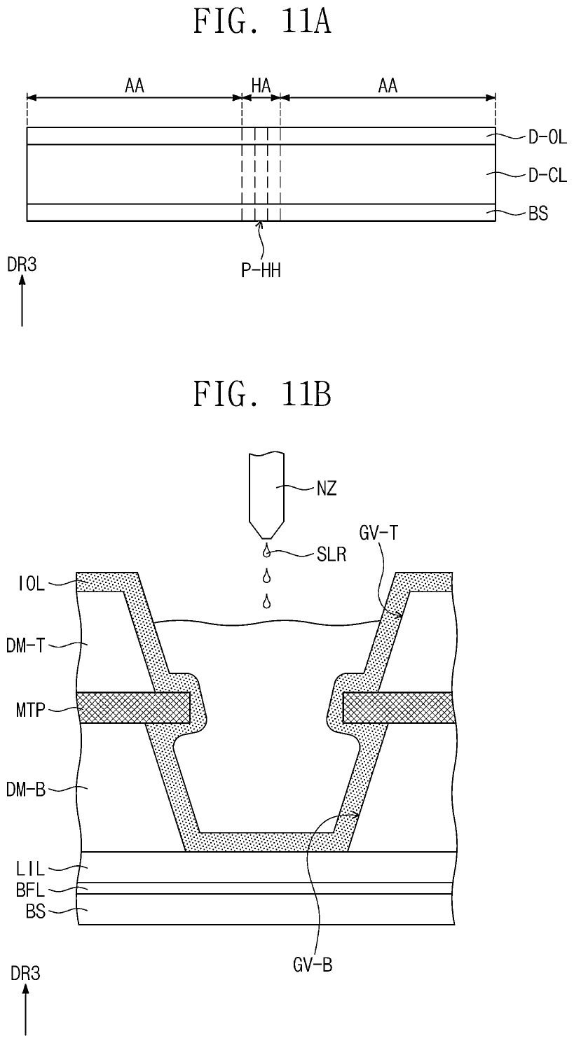

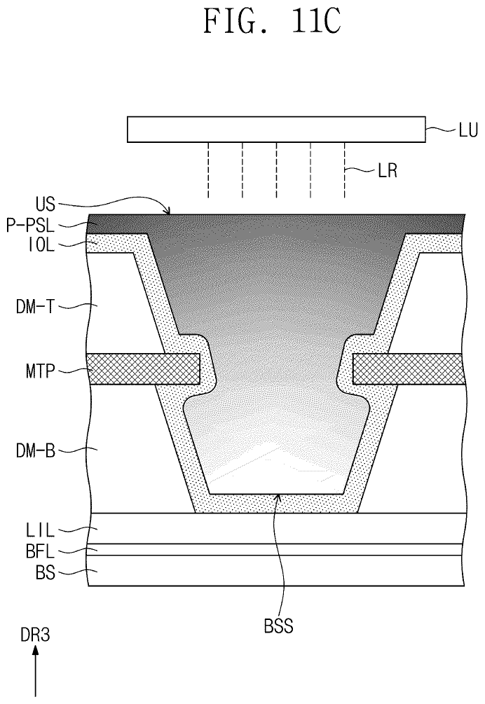

FIGS. 11A to 11C are views schematically showing a step in a method for manufacturing a display device according to an embodiment. FIG. 12 is a block diagram briefly showing a step of forming a barrier layer according to an embodiment. Hereinafter, a method for manufacturing a display device of an embodiment will be described with reference to FIGS. 11A to 12.

The method for manufacturing a display device of an embodiment may include providing a base layer, forming a circuit layer, forming dam portions, forming a display element layer, forming an inorganic encapsulation film, and forming a barrier layer. In the description of the method for manufacturing a display device of an embodiment, the same description may apply to the same components as those of the display device described with reference to FIGS. 1 to 10.

FIG. 11A shows a portion of a display module in which a base layer BS, a circuit layer D-CL, and a display element layer D-OL are sequentially disposed. The base layer BS may include a hole region HA in which a through-hole HH (FIG. 6) is defined, and a display region AA positioned adjacent to the hole region HA. Referring to FIG. 11A, the hole region HA may include a preliminary hole P-HH portion in which the through-hole HH (FIG. 6) is formed later.

The circuit layer D-CL including a conductive pattern and a plurality of insulating layers may be formed on the provided base layer BS. Meanwhile, in the forming of the circuit layer D-CL, forming dam portions may be performed.

The dam portions DM1, DM2, and DM3 (FIG. 6) may be formed in the hole region HA. The forming of the dam portions DM1, DM2, and DM3 (FIG. 6) may be performed in the same steps as forming some of the insulating layers of the circuit layer D-CL and forming some of the conductive patterns. The dam portions DM1, DM2, and DM3 (FIG. 6) may include a dam layer disposed on the same layer as some of the insulating layers of the circuit layer D-CL, and may include grooves GV1, GV2, and GV3 (FIG. 6) defined in the hole region HA by the dam layers. In addition, the dam portions DM1, DM2, and DM3 (FIG. 6) may include a conductive pattern MTP including a tip portion protruding toward the inside of the groove.

After the forming of the circuit layer D-CL and the forming of the dam portions are performed, forming the display element layer D-OL may be performed. After the forming of the circuit layer D-CL, forming a display element layer D-OL including a light emitting element LD (FIG. 5) on the circuit layer D-CL may be performed.

After the forming of the display element layer D-OL, forming an inorganic encapsulation film IOL covering the light emitting element and the dam portions may be performed. The inorganic encapsulation film IOL may be formed through chemical vapor deposition (CVD). The inorganic encapsulation film IOL may be provided throughout the hole region HA and the display region AA.

After the forming of the inorganic encapsulation film IOL, forming a barrier layer PSL (FIG. 6) disposed directly on the inorganic encapsulation film IOL and containing inorganic polysilazane may be performed.

FIGS. 11B and 11C show a portion of forming a barrier layer as an example. The forming of the barrier layer may include providing a silazane resin composition SLR using an inkjet printing method to form a preliminary barrier layer P-PSL, and irradiating the preliminary barrier layer P-PSL with laser light LR to form the barrier layer.

FIG. 11B shows providing a silazane resin composition SLR using an inkjet printing method as an example. The silazane resin composition SLR may be provided directly on the inorganic encapsulation film IOL through a nozzle NZ. The silazane resin composition SLR may fill the concave portions GV-B and GV-T and may be provided to have a sufficient thickness to cover the inorganic encapsulation film IOL.

The silazane resin composition SLR may include a silazane compound containing the unit represented by Formula 1 described above and an organic solvent. The silazane resin composition SLR contains an organic solvent and may thus be easily discharged through the nozzle NZ, and is provided repeatedly using an inkjet printing device and may thus be regulated to have a viscosity that allows a sufficient thickness. The organic solvent is one that may dissolve the silazane compound and may be used without limitation as long as the solvent is usable in an inkjet printing device.

FIG. 11C shows irradiating a preliminary barrier layer P-PSL with laser light LR to form a barrier layer as an example. A laser irradiation device LU may be disposed on an upper surface US of the preliminary barrier layer P-PSL provided to fill the concave portions GV-B and GV-T. The laser light LR may be emitted from the upper surface US and delivered toward a lower surface BSS of the preliminary barrier layer P-PSL.

The laser light LR is emitted to be delivered from the upper surface US to the lower surface BSS of the preliminary barrier layer P-PSL, and accordingly, the silazane compound of the preliminary barrier layer P-PSL is highly polymerized and cured at a portion adjacent to the upper surface US, and the extent of polymerization and curing of the silazane compound may decline toward the lower surface BSS. In FIG. 11C, the gray scale is shown to change from the upper surface US to the lower surface BSS, and that is, in an embodiment, when the laser light LR is emitted to the preliminary barrier layer P-PSL, polymerization of the silazane compound may be performed in a direction toward the lower surface BSS from the upper surface US. Accordingly, an inorganic film of silicon nitride or silicon oxynitride may be formed on the upper surface US of the finally formed barrier layer PSL (FIG. 6). Meanwhile, when the laser light LR fails to sufficiently reach the lower surface BSS, a barrier layer in the form of a silazane-based compound may be formed in a portion adjacent to the lower surface BSS.

In addition, a portion adjacent to the upper surface US sufficiently irradiated with the laser light LR may exhibit a greater refractive index value than the lower surface BSS which is not sufficiently irradiated with the laser light LR. In an embodiment, the barrier layer PSL (FIG. 6) may have a decreasing refractive index in the direction toward the lower surface BSS from the upper surface US.

In an embodiment, the laser light provided to the preliminary barrier layer P-PSL may have a wavelength of about 172 nanometers (nm). Meanwhile, the irradiating of the preliminary barrier layer P-PSL with the laser light LR to form a barrier layer may be performed in an N₂ atmosphere or an O₂ atmosphere.

When the irradiating of the preliminary barrier layer P-PSL with the laser light LR to form a barrier layer is performed in an N₂ atmosphere, the barrier layer PSL (FIG. 6) may include silicon nitride. In addition, when the irradiating of the preliminary barrier layer P-PSL with the laser light LR to form a barrier layer is performed in an O₂ atmosphere, the barrier layer PSL (FIG. 6) may include silicon oxynitride.

FIG. 12 is a block diagram briefly showing a step of forming a barrier layer according to an embodiment. In FIG. 12, “SLU” indicates a silazane compound unit. “SLU” may include the unit of Formula 1 described above. In an embodiment, for example, “SLU” may be a silazane compound unit having the structure of Formula 2 described above.

When a silazane compound unit SLU is subjected to reaction with the laser light LR under specific gas GAS conditions, inorganic polysilazane PS may be formed. As described above, when the gas GAS is N₂, inorganic polysilazane PS may turn into silicon nitride (SiNx), and when the gas GAS is O₂, inorganic polysilazane PS may turn into silicon oxynitride (SiON).

Meanwhile, the silazane compound unit SLU provided in the method for manufacturing a display device according to an embodiment may not entirely turn into inorganic polysilazane PS having the same compound composition and physical properties. For example, in an embodiment, the barrier layer PSL (FIG. 6) may include a first portion containing inorganic polysilazane PS having a high refractive index value, a second portion containing unpolymerized silazane compound units SLU, and a third portion containing inorganic polysilazane PS having a partially reduced refractive index value compared to the first portion, depending on the irradiation amount of the laser light LR.

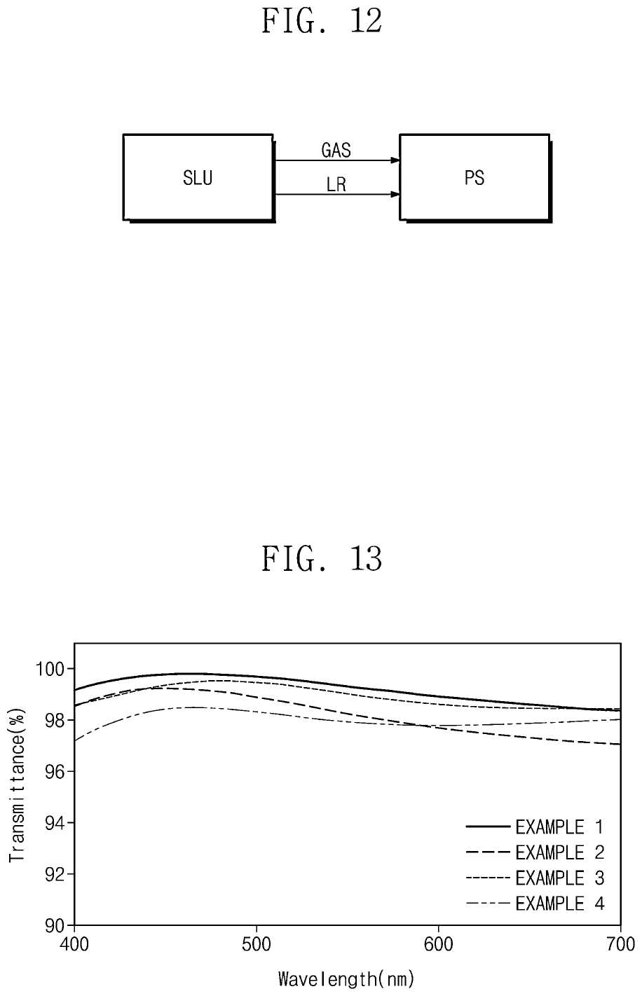

FIG. 13 is a view showing light transmittance characteristics of a barrier layer prepared in a step of the method for manufacturing a display device of an embodiment. FIG. 13 shows the light transmittance characteristics of a barrier layer according to wavelength. Examples 1 to 4 each correspond to different manufacturing process conditions for the barrier layer. In Example 1, a preliminary barrier layer P-PSL (FIG. 11C) having a thickness of about 1500 Å is irradiated with laser light with an energy of 2 joules (J), and in Example 2, a preliminary barrier layer P-PSL (FIG. 11C) having a thickness of about 1500 Å is irradiated with laser light with an energy of 10 J. In Example 3, a preliminary barrier layer P-PSL (FIG. 11C) having a thickness of about 3,000 Å is irradiated with laser light with an energy of 2 J, and in Example 4, a preliminary barrier layer P-PSL (FIG. 11C) having a thickness of about 3,000 Å is irradiated with laser light with an energy of 10 J.

Referring to the results of Examples 1 to 4, it is seen that a high light transmittance of greater than 96% is observed in the visible light region. That is, when the barrier layer containing an inorganic polysilazane compound is included as an encapsulation layer, a display device may exhibit excellent reliability and may also exhibit excellent display quality due to high light transmittance.

The display device of an embodiment is directly disposed on the inorganic encapsulation film and includes the barrier layer containing an inorganic polysilazane compound, and may thus exhibit excellent reliability. That is, in the display device of an embodiment, an inorganic film bonding between the barrier layer containing the inorganic polysilazane compound and the inorganic encapsulation film is formed to sufficiently protect the components of a display panel, resulting in high reliability. In particular, a single barrier layer containing an inorganic polysilazane compound effectively blocks moisture, oxygen, and chemicals delivered through-holes formed in a display module to replace a typical stack structure of organic and inorganic encapsulation films, thereby providing excellent reliability.

The method for manufacturing a display device of an embodiment includes forming a barrier layer containing inorganic polysilazane directly on the inorganic encapsulation film, and may thus exhibit excellent process economic efficiency. In the forming of the barrier layer, a silazane resin composition is provided to have a sufficient thickness through an inkjet printing method and laser light is emitted to ensure that the barrier layer has a high refractive index value, and accordingly, the barrier layer may sufficiently cover the components of a display panel and exhibit excellent encapsulation performance. That is, processes simplified through the method for manufacturing a display device of an embodiment allows the manufacture of a display device and allows the display device to have excellent reliability.

A display device of an embodiment includes a barrier layer containing a silazane-based compound and thus has high adhesion to an inorganic encapsulation film, thereby effectively protecting a display panel and exhibiting excellent reliability.

In addition, a display device of an embodiment includes a barrier layer containing a silazane-based compound directly disposed on an inorganic encapsulation film and thus allows the barrier layer to replace the typical stack structure of an organic encapsulation film and an upper inorganic encapsulation film to simplify manufacturing processes and effectively cover a groove portion defined around a hole, thereby showing excellent reliability.

A method for manufacturing a display device of an embodiment includes providing a silazane-based resin composition directly on an inorganic encapsulation film to form a barrier layer, and may thus form a silazane-based barrier layer having a sufficient thickness to manufacture a highly reliable display device through a simplified process.

Although the present disclosure has been described with reference to a preferred embodiment of the invention, it will be understood that the invention should not be limited to these preferred embodiments but various changes and modifications may be made by those skilled in the art without departing from the spirit and scope of the present disclosure.

Accordingly, the technical scope of the invention is not intended to be limited to the contents set forth in the detailed description of the specification, but is intended to be defined by the appended claims.

What is claimed is:

1. A display device comprising:
a circuit layer including a transistor and a plurality of insulating layers;
a display element layer disposed on the circuit layer and including a light emitting element electrically connected to the transistor;
an inorganic encapsulation film disposed on the display element layer; and
a barrier layer directly disposed on the inorganic encapsulation film and containing an inorganic polysilazane compound.

2. The display device of claim 1, wherein the barrier layer comprises an inorganic polymer layer containing silicon (Si) and nitrogen (N), or an inorganic polymer layer containing Si, N, and oxygen (O).

3. The display device of claim 1, wherein the barrier layer has a refractive index of about 1.59 to about 1.90.

4. The display device of claim 1, wherein the barrier layer has a refractive index at a first portion adjacent to the inorganic encapsulation film, which is smaller than a refractive index at a second portion spaced apart from the inorganic encapsulation film.

5. The display device of claim 1, wherein a refractive index of the barrier layer increases in a direction away from the inorganic encapsulation film.

6. The display device of claim 1, wherein a first portion of the barrier layer, which is adjacent to the inorganic encapsulation film, comprises a silazane-based compound having a repeating unit of Formula 1 below, and
a second portion of the barrier layer, which is positioned on the first portion, comprises silicon nitride or silicon oxynitride, 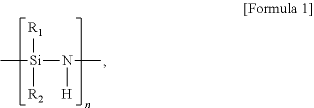
wherein in Formula 1 above, R₁ and R₂ are each independently a hydrogen atom, an alkyl group having 1 to 10 carbon atoms, or an aryl group having 6 to 30 ring-forming carbon atoms, and
n is an integer of 2 or greater.

7. The display device of claim 1, wherein the barrier layer has a thickness of about 1,000 Å to about 100,000 Å.

8. The display device of claim 7, wherein when the thickness of the barrier layer is about 3,000 angstroms (Å) or less, the barrier layer is a silicon nitride layer or a silicon oxynitride layer.

9. A display device comprising:
an electronic module; and
a display module including a hole region including a hole defined to overlap the electronic module, and a display region spaced apart from the hole in a plan view,
wherein the display module includes:
a base layer;
a circuit layer disposed on the base layer and including a plurality of insulating layers;
a display element layer disposed on the circuit layer and including a light emitting element and a pixel defining film;
a plurality of dam portions disposed on the base layer in the hole region;
an inorganic encapsulation film covering the display element layer and the dam portions; and
a barrier layer directly disposed on the inorganic encapsulation film and containing an inorganic polysilazane compound.

10. The display device of claim 9, wherein the dam portions comprise:
a first dam portion surrounding the hole; and
a second dam portion surrounding the first dam portion in the plan view, and
wherein a groove is defined between the first dam portion and the second dam portion.

11. The display device of claim 10, wherein the groove is filled with the barrier layer.

12. The display device of claim 10, wherein the first dam portion and the second dam portion each comprise:
a first dam layer disposed in a same layer as one of the plurality of insulating layers;
a second dam layer disposed on the first dam layer; and
a conductive pattern including a tip portion protruding in a direction toward an inside of the groove and a direction away from the groove, and disposed between the first dam layer and the second dam layer.

13. The display device of claim 12, wherein the plurality of insulating layers comprise:
a lower insulating layer including a plurality of inorganic films sequentially disposed on the base layer;
a first organic film disposed on the lower insulating layer; and
a second organic film disposed on the first organic film, and
the first dam layer is disposed in a same layer as the first organic film, and the second dam layer is disposed in a same layer as the second organic film.

14. The display device of claim 12, wherein the groove comprises a first concave portion defined by the first dam layer, and a second concave portion defined by the second dam layer on the first concave portion, and
the barrier layer covers a lower surface of the tip portion and fills the first concave portion.

15. The display device of claim 11, wherein the barrier layer comprises an inorganic polymer layer containing Si and N, or an inorganic polymer layer containing Si, N, and O, and
the barrier layer has a refractive index of about 1.59 to about 1.90.

16. The display device of claim 11, wherein the barrier layer has a refractive index at a first portion adjacent to the inorganic encapsulation film, which is smaller than a refractive index at a second portion spaced apart from the inorganic encapsulation film.

17. A method for manufacturing a display device, the method comprising:
providing a base layer including a hole region in which a through-hole is defined, and a display region adjacent to the hole region;
forming a circuit layer including a conductive pattern and a plurality of insulating layers on the base layer;
forming a plurality of dam portions including a dam layer disposed in a same layer as some of the insulating layers, wherein the dam portions define a groove in the hole region;
forming a display element layer including a light emitting element on the circuit layer;
forming an inorganic encapsulation film covering the light emitting element and the dam portions; and
forming a barrier layer directly disposed on the inorganic encapsulation film and containing an inorganic polysilazane compound.

18. The method of claim 17, wherein the forming of the barrier layer comprises:
providing a silazane resin composition through a method of inkjet printing to form a preliminary barrier layer; and
irradiating the preliminary barrier layer with laser light to form the barrier layer.

19. The method of claim 18, wherein the silazane resin composition comprises a silazane compound containing a unit represented by Formula 1 below and an organic solvent, 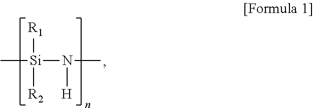
wherein in Formula 1 above, R₁ and R₂ are each independently a hydrogen atom, an alkyl group having 1 to 10 carbon atoms, or an aryl group having 6 to 30 ring-forming carbon atoms, and
n is an integer of 2 or greater.

20. The method of claim 18, wherein the laser light is a laser having a wavelength of about 172 nanometers (nm), and
the forming of the barrier layer is performed in an N₂ atmosphere or an O₂ atmosphere.
